(19) United States
(12) Patent Application Publication
(10) Pub. No.: US 2011/0214707 A1
(43) Pub. Date: Sep. 8, 2011

(54) THERMOELECTRIC GENERATOR

(75) Inventors: Takashi SUZUKI, Kawasaki (JP); Takuya Nishino, Kawasaki (JP)

(73) Assignee: FUJITSU LIMITED, Kawasaki (JP)

(21) Appl. No.: 13/038,761

(22) Filed: Mar. 2, 2011

(30) Foreign Application Priority Data
Mar. 8, 2010 (JP) JP 2010-050829
Sep. 10, 2010 (JP) JP 2010-203426
Jan. 21, 2011 (JP) JP 2011-010795

(51) Int. Cl. H01L 35/30

(52) U.S. Cl. 136/205

(57) ABSTRACT

Thermoelectric generating parts having a plate-shape or film-shape are stacked in a thickness direction. Each of the thermoelectric generating parts generates an electric power as a temperature difference is generated in the thickness direction. Thermal conducting members are disposed between two of the thermoelectric generating parts adjacent in a stacked direction and on outer surfaces of outermost two thermoelectric generating parts. A first thermal coupling member is connected to and thermally coupled to the every other thermal conducting members. A second thermal coupling member is connected to and thermally coupled to the thermal conducting members not connected to the first thermal coupling member.

### CROSS-REFERENCE TO RELATED APPLICATION

This application is based upon and claims the benefit of priority of the prior Japanese Patent Applications No. JP 2010-050829, filed on Mar. 8, 2010, No. JP 2010-203426 filed on Sep. 10, 2010, and No. JP2011-010795 filed on Jan. 21, 2011, the entire contents of which are incorporated herein by reference.

### FIELD

The embodiments discussed herein are related to a thermoelectric generator for converting thermal energy into an electric energy by using a temperature difference.

### BACKGROUND

Various types of clean energies have been paid attention along with high level of interest on environment-related issue. One of clean energies is thermoelectric generation converting thermal energy into electric energy by using a temperature difference.

A thin film thermoelectric generating device having thermoelectric conversion material formed on an insulating film having flexibility is known. By attaching materials having high thermal conductivity on the insulating film in such a manner that the materials are mutually shifted in in-plane direction, a temperature difference in an in-plane direction is generated from a temperature difference in the thickness direction. Thermoelectric conversion is performed by using a temperature difference in the in-plane direction.

A thermoelectric generating device is known having a structure that thermoelectric conversion material is disposed from one surface of a film to the other surface of the film. In this thermoelectric generating device, thermoelectric conversion is performed by a temperature difference in the thickness direction.

A thermoelectric conversion device is known having film-shaped thermoelectric conversion elements and thermal insulating plates which are alternately stacked. Thermoelectric generation is performed by using a temperature difference in the direction perpendicular to the lamination direction. Since the thermal insulating plates are sandwiched, thermal conduction from a high temperature side to a low temperature side is able to be suppressed.
[Patent Document 1] Japanese Laid-open Patent Publication No. 2006-186255
[Patent Document 2] Japanese Laid-open Patent Publication No. HEI 8-153898
[Non-Patent Document] J. Micromech. Microeng. Vol. 15 (2005) S233-S238

### SUMMARY

It is an object of the present invention to provide a thermoelectric generator capable of improving an electric power generation ability compared to a conventional thermoelectric generator.

According to one aspect of the embodiments, there is provided a thermoelectric generator including:

thermoelectric generating parts having a plate-shape or film-shape and stacked in a thickness direction, each of the thermoelectric generating parts generating an electric power as a temperature difference is generated in the thickness direction;

thermal conducting members disposed between two of the thermoelectric generating parts adjacent in a stacked direction and on outer surfaces of outermost two thermoelectric generating parts;

a first thermal coupling member connected to and thermally coupled to the every other thermal conducting members disposed in the stacked direction; and

a second thermal coupling member connected to and thermally coupled to the thermal conducting members not connected to the first thermal coupling member.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a cross sectional view illustrating a thermoelectric generator according to a first embodiment.

FIG. 2 is a cross sectional view illustrating a thermoelectric generator according to a second embodiment.

FIG. 3Aa, FIG. 3Ab to FIG. 3Ea, FIG. 3Eb are planar views and cross sectional views of the thermoelectric generator of the second embodiment at intermediate stages of manufacturing process.

FIG. 3F is a cross sectional view of the thermoelectric generator of the second embodiment at an intermediate stage of manufacturing process.

FIG. 4 is a cross sectional view of a thermoelectric generator according to a third embodiment.

FIG. 5 is a developed planar view of a flexible film of a thermoelectric generator of the third embodiment and a graph illustrating a temperature distribution.

FIG. 6A and FIG. 6B are a broken perspective view and a cross sectional view of a thermoelectric generator according to a fourth embodiment.

FIG. 7A and FIG. 7B are a broken perspective view and a cross sectional view of a thermoelectric generator according to a fifth embodiment.

FIG. 8 is a developed planar view of a flexible film of a thermoelectric generator according to a sixth embodiment.

FIG. 9 is a broken perspective view of the thermoelectric generator of the sixth embodiment.

FIG. 10 is a cross sectional view of a thermoelectric generator according to a seventh embodiment.

FIG. 11 is a cross sectional view of a thermoelectric generator according to an eighth embodiment at an intermediate stage of manufacturing process.

FIG. 12 is a cross sectional view of the thermoelectric generator of the eighth embodiment.

FIG. 13 is a cross sectional view of a thermoelectric generator according to a ninth embodiment.

FIG. 14 is a developed perspective view of a flexibly film of the thermoelectric generator of the ninth embodiment and a graph illustrating a temperature distribution.

FIG. 15 is a developed planar view of a flexible film of a thermoelectric generator according to a tenth embodiment.

FIG. 16 is a perspective view of a thermoelectric generator according to an eleventh embodiment at an intermediate stage of manufacturing process according to an eleventh embodiment.

FIG. 17 is a cross sectional view of the thermoelectric generator of the eleventh embodiment.

FIG. 18 is a cross sectional view of a thermoelectric generator according to a twelfth embodiment.

FIG. 19 is a cross sectional view of a thermoelectric generator according to a thirteenth embodiment

FIG. 20A to FIG. 20C are cross sectional views of samples, temperature distributions of which are simulated.

FIG. 21 is a graph illustrating temperature distribution simulation results.

FIG. 22 is a cross sectional view of a thermoelectric generator according to a fourteenth embodiment at an intermediate stage of manufacturing process.

FIG. 23 is a cross sectional view of a thermoelectric generator according to a fourteenth embodiment.

FIG. 24A is a cross sectional view of a thermoelectric generator according to a fifteenth embodiment at an intermediate stage of manufacturing process, and

FIG. 24B is a cross sectional view of the thermoelectric generator according to the fifteenth embodiment.

FIG. 25A is a cross sectional view of a thermoelectric generator according to a modification of the fifteenth embodiment at an intermediate stage of manufacturing process, and FIG. 25B is a cross sectional view of the thermoelectric generator according to the modification of the fifteenth embodiment.

FIG. 26A and FIG. 26B are a planar view and a cross sectional view of a thermoelectric generator according to a seventeenth embodiment at an intermediate stage of manufacturing process, respectively.

FIG. 27 is a perspective view of the thermoelectric generator according to the seventeenth embodiment at an intermediate stage of manufacturing process.

FIG. 28 is a cross sectional view of the thermoelectric generator of the seventeenth embodiment.

FIG. 29A and FIG. 29B are a planar view and a cross sectional view of a sample used for a temperature distribution simulation of the thermoelectric generator of the seventeenth embodiment, and FIG. 29C is a cross sectional view of a thermoelectric generator according to a comparative example.

FIG. 30 are graphs illustrating temperature distribution simulation results of the thermoelectric generators of the seventeenth embodiment and the comparative example.

FIG. 31A is a cross sectional view of a thermoelectric generator according to an eighteenth embodiment.

FIG. 32 is a cross sectional view of a thermoelectric generator according to a nineteenth embodiment at an intermediate stage of manufacturing process.

FIG. 33 is a cross sectional view of the thermoelectric generator of the nineteenth embodiment.

FIG. 34 to FIG. 36 are cross sectional views of a thermoelectric generator according to a twentieth embodiment at intermediate stages of manufacturing process.

FIG. 37 is a cross sectional view of the thermoelectric generator of the twentieth embodiment.

### DESCRIPTION OF EMBODIMENTS

By referring to the accompanying drawings, description will be made on first to twentieth embodiments.

### First Embodiment

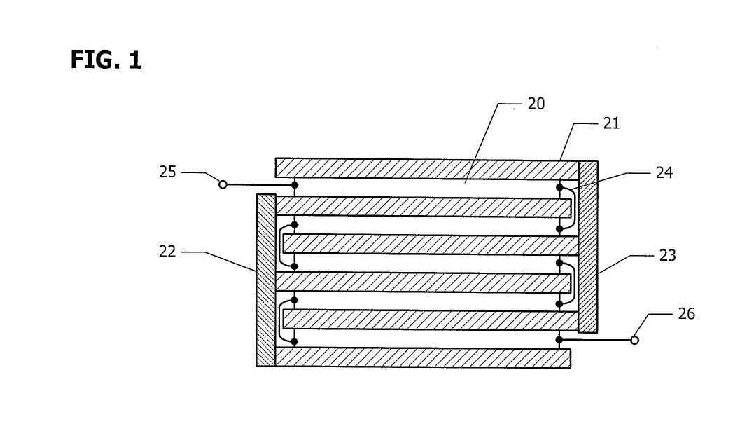

FIG. 1 is a cross sectional view of a thermoelectric generator of the first embodiment. Plate-shaped or film-shaped thermoelectric generating devices 20 and plate-shaped or film-shaped thermal conducting members 21 are alternately stacked. At least three thermoelectric generating devices 20 are stacked. The thermal conducting members 21 are disposed on both sides in the stacked direction. Each thermoelectric generating device 20 generates an electric power when a temperature difference is generated in the thickness direction of the thermoelectric generating device 20.

A first thermal coupling member 22 is connected to every other thermal conducting members 21 disposed in the stacked direction. A second thermal coupling member 23 is connected to the thermal conducting members 21 not connected to the first thermal coupling member 22. The first thermal coupling member 22 is thermally coupled to the thermal conducting members 21 connected thereto, and the second thermal coupling member 23 is thermally coupled to the thermal conducting members 21 connected thereto.

An interlayer wiring 24 electrically connects the adjacent thermoelectric generating devices 20 in the stacked direction to each other. For example, a plurality of thermoelectric generating devices 20 are serially connected. One of outermost thermoelectric generating devices 20 is connected to a terminal 25, and the other is connected to a terminal 26. A generated electric power is extracted from the terminals 25 and 26.

The number of stacked thermoelectric generating devices 20 is odd, whereas the number of stacked thermal conducting embers 21 is even. One of the outermost thermal conducting members 21 is therefore connected to the first thermal coupling member 22, and the other is connected to the second thermal coupling member 23. The first thermal coupling member 22, the second thermal coupling member 23 and the thermal conducting member 21 are made of material having a higher thermal conductivity than that of the thermoelectric generating devices 20.

One of the outermost thermal conducting members 21, e.g., the thermal conducting member 21 connected to the first thermal conducting member 22 takes a higher temperature, and the other of the outermost thermal conducting member 21, e.g., the thermal conducting member 21 connected to the second thermal coupling member 23 takes a lower temperature. As this temperature difference is generated, a temperature of all the thermal conducting members 21 connected to the first thermal coupling member 22 becomes higher than a temperature of the thermal conducting members 21 connected to the second thermal coupling member 23. A temperature difference is therefore generated at each thermoelectric generating device 20 in the thickness direction. This temperature difference generates an electric power. Temperature gradients in the thickness direction of the adjacent thermoelectric generating devices 20 in the stacked direction are opposite in direction. Although a temperature difference given to each thermoelectric generating device 20 becomes slightly lower than a temperature difference between the uppermost surface and lowermost surface of the stacked structure, it is sufficiently higher than a temperature difference when the temperature difference between the uppermost surface and lowermost surface is equally divided to the plurality of thermoelectric generating devices 20. By stacking the thermoelectric generating devices 20, it becomes therefore possible to improve an electric power generating ability per unit area.

### Second Embodiment

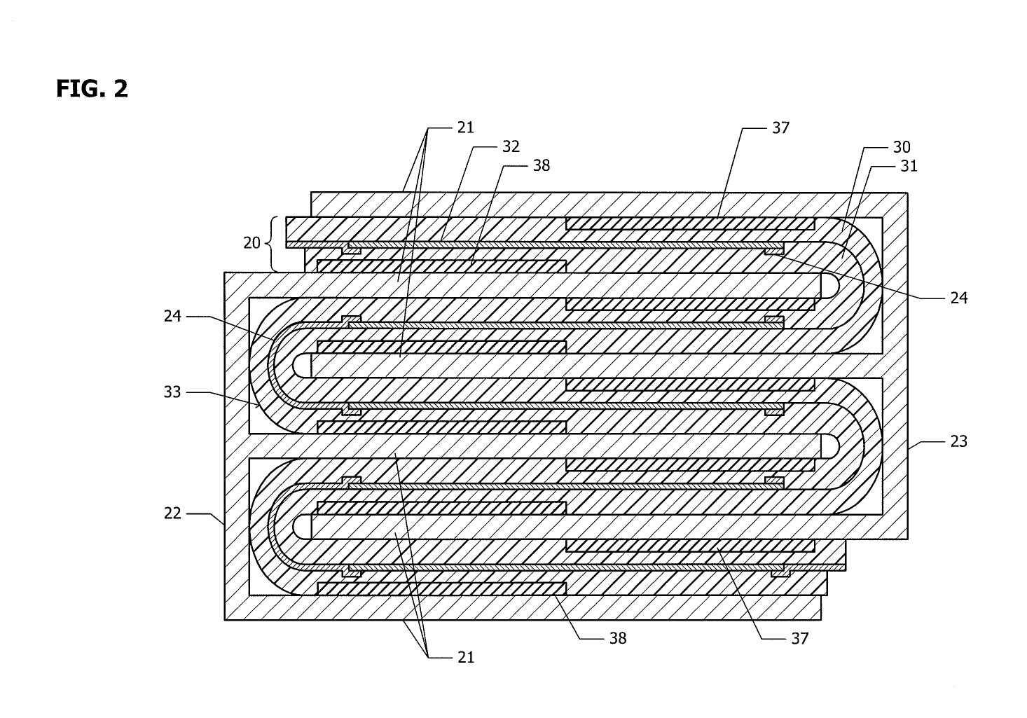

FIG. 2 illustrates a cross sectional view of a thermoelectric generator of the second embodiment. A belt-like first flexible film 30 and a second flexible film 31 are bonded together, and folded up into concertinas having five layers in the longitudinal direction. Of the folded first flexible film 30 and the second flexible film 31, each flat plane portion superposed upon in the thickness direction corresponds to one thermoelectric generating device 20 (FIG. 1). Interlayer wirings 24 are disposed between the first flexible film 30 the and second flexible film 31 in folded portions 33.

Each thermoelectric generating device 20 includes a first good thermal conductor 37 disposed on an outer surface of the first flexible film 30, a second good thermal conductor 38 disposed on an outer surface of the second flexible film 31, and a thermoelectric conversion pattern 32 sandwiched between the first flexible film 30 and the second flexible film 31. The first good thermal conductor 37 and the second good thermal conductor 38 are made of material having a higher thermal conductivity than that of the first flexible film 30 and the second flexible film 31. For the first flexible film 30 and the second flexible film 31, for example, insulating material such as polyimide, kapton (registered trademark), polycarbonate, polyethylene, polyethyleneterephthalate (PET), polysulfone (PSF), polyetherethylketone (PEEK), and polyphenylenesulfide (PPS) may be used. From these materials, proper materials are selected by considering a film forming condition of thermoelectric conversion material, a use condition of the thermoelectric generator, and the like. For the first good thermal conductor 37 and the second good thermal conductor 38, for example, metal such as copper may be used.

The first good thermal conductor 37 and the second good thermal conductor 38 are displaced at positions different from each other in an in-plane direction. For example, in FIG. 2, the first good conductor 37 and the second good conductor 38 are displaced in a horizontal direction, i.e., in a longitudinal direction of the first flexible film 30 and the second flexible film 31 before being folded.

A plate-shaped thermal conducting member 21 is disposed between the thermoelectric generating devices 20. A first thermal coupling member 22 is connected to every other thermal conducting members 21. In FIG. 2, the first thermal coupling member 22 is connected to the lowermost thermal conducting member 21 and every odd-numbered thermal conducting members 21 as counted from the lowermost thermal conducting member 21. A second thermal coupling member 23 is connected to every even-numbered thermal conducting members 21.

A folded portion 33 of the folded stacked structure appears at mutually opposing two side walls (left and right side walls as viewed in FIG. 2). The first thermal coupling member 22 is disposed along one of the side walls (the left side wall in FIG. 2), and the second thermal coupling member 23 is disposed along the other of the side walls (the right side wall in FIG. 2).

Next, description will be made on a manufacture method for the thermoelectric generator of the second embodiment.

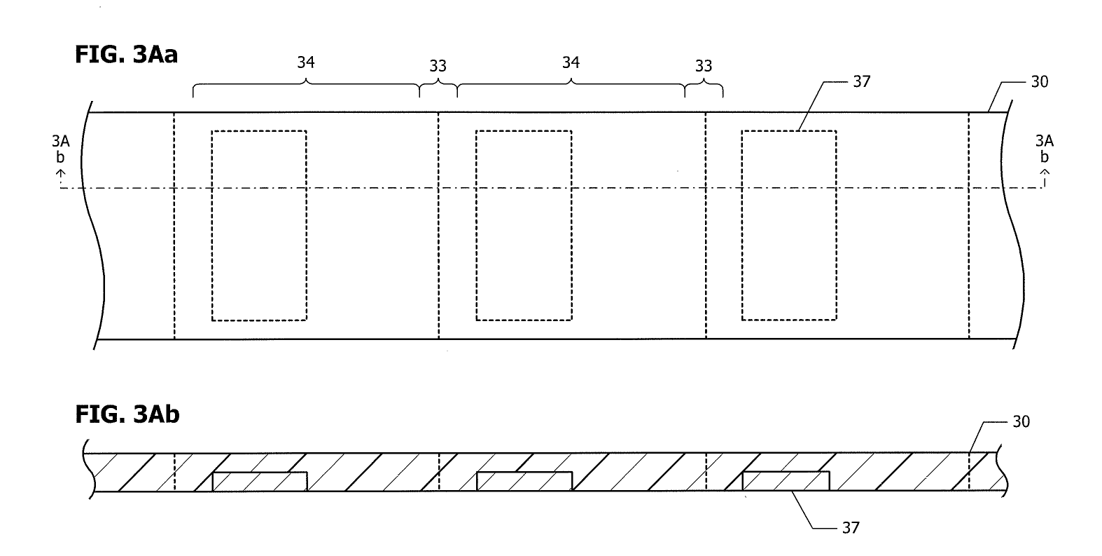

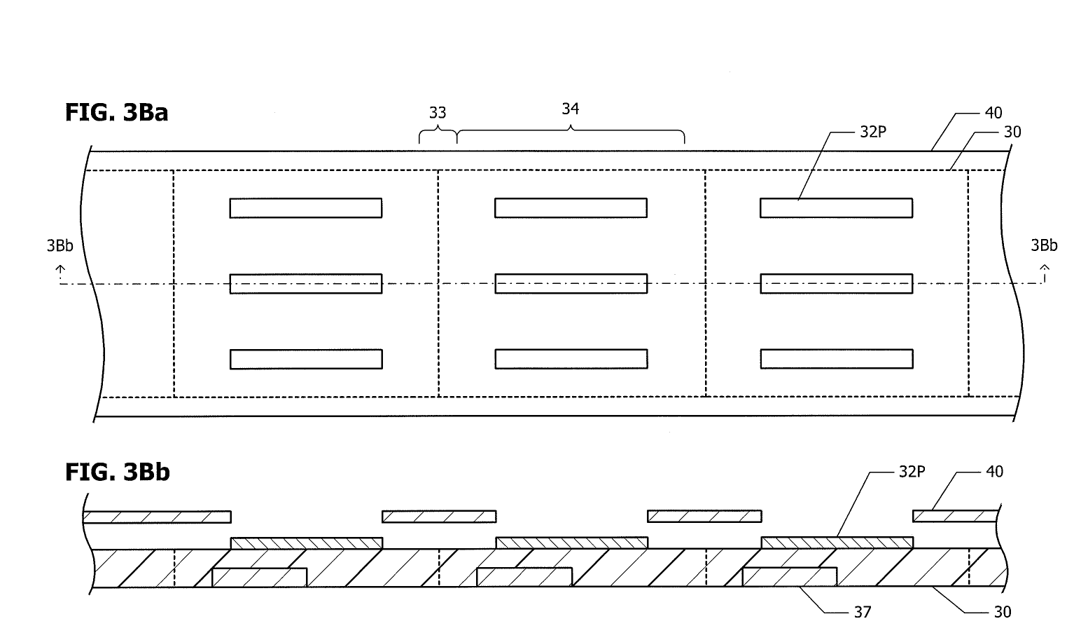

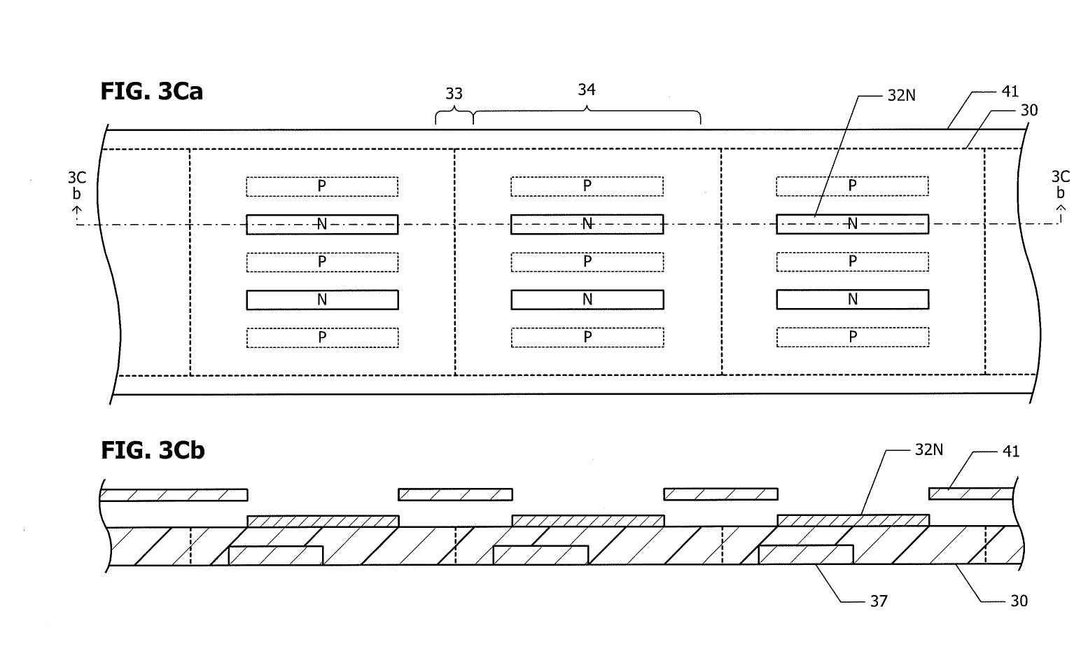

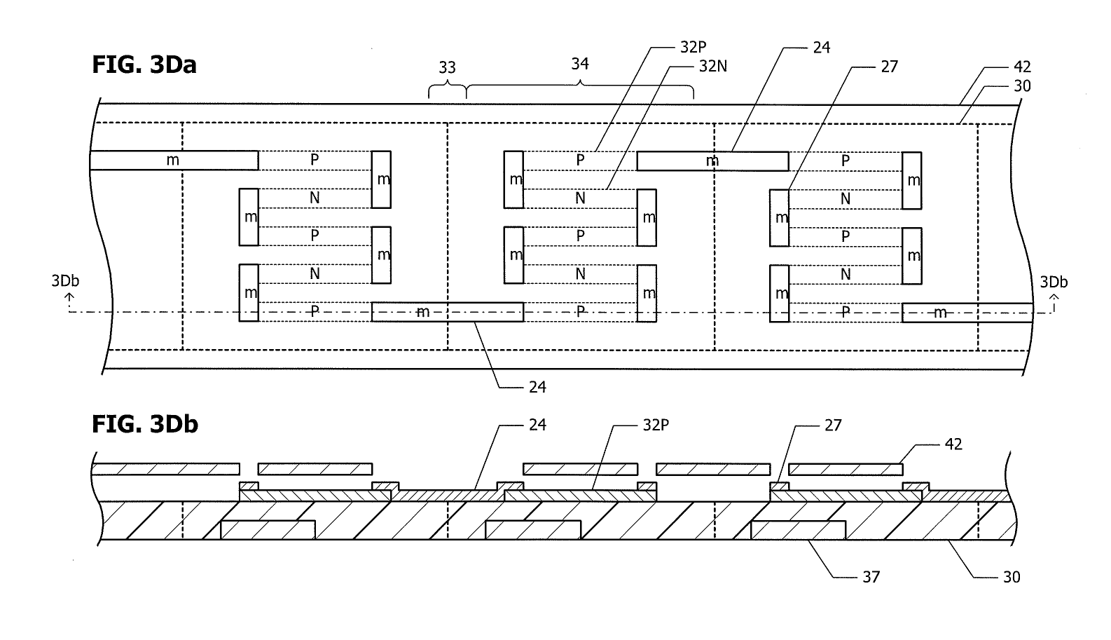

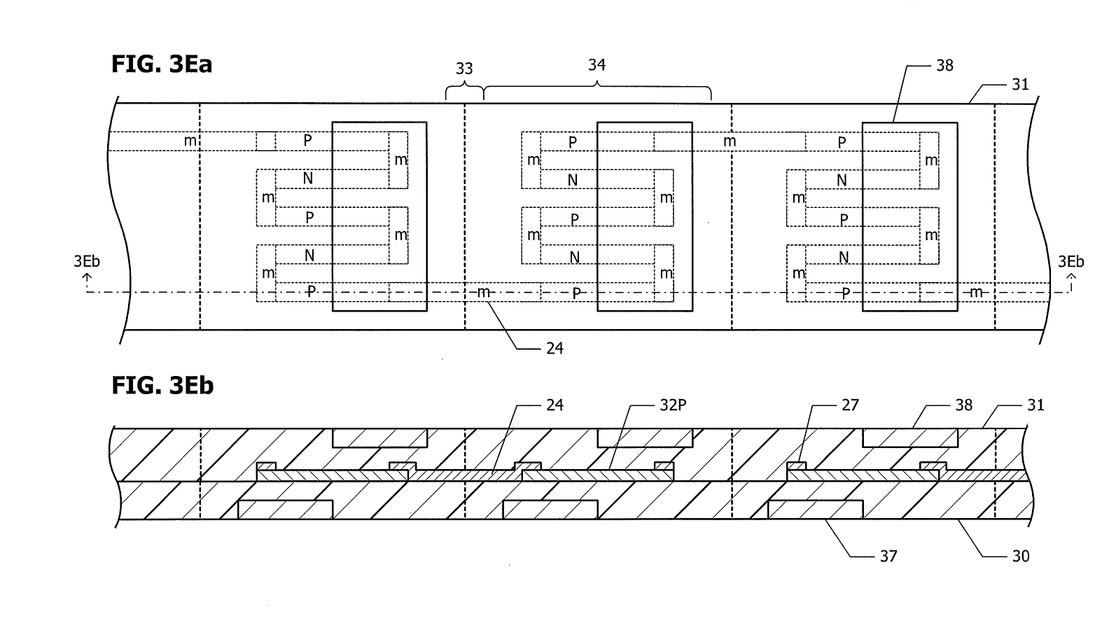

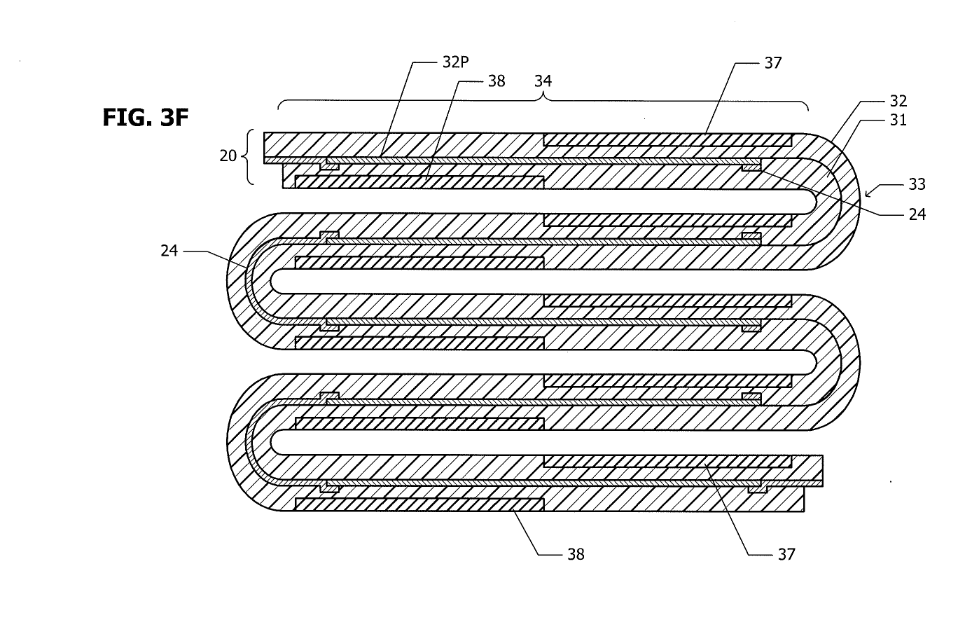

As illustrated in FIG. 3Aa, five thermoelectric generating parts 34 are defined on the band-like first flexible film 30. The thermoelectric generating parts 34 are disposed in one line on the first flexible film 30 in the longitudinal direction. Folded portions 33 are defined between adjacent thermoelectric generating parts 34. FIG. 3Ab is a cross sectional view taken along one-dot chain line 3Ab-3Ab in FIG. 3Aa. For the first flexible film 30, for example, a polyimide film having a thickness of 50 μm and a width of 100 mm is used. A size of each of the thermoelectric generating parts 34 in the longitudinal direction of the first flexible film 30 is, e.g., within a range of 3 mm to 50 mm. The number of thermoelectric generating parts 34 may be an odd number other than “5”.

One first good thermal conductor 37 is fabricated on one surface of each of the thermoelectric generating parts 34 of the first flexible film 30. For the first good thermal conductor 37, for example, a copper foil having a thickness of 25 μm is used. The first good thermal conductor 37 is fabricated in the first flexible film 30 by burying the first good thermal conductor 37 in a recess formed by grinding a partial area of the surface of the first flexible film 30. The first good thermal conductor 37 is disposed in each inner region of the thermoelectric generating part 34 at a position displaced toward one side in the longitudinal direction. In the second embodiment, the first good thermal conductors 37 are disposed at positions displaced toward the same side (on the left side in FIG. 3Aa and FIG. 3Ab) in all thermoelectric generating parts 34.

The first flexible film 30 having the first good thermal conductors 37 may be formed by the following process. Copper foils are arranged on a work table. Polyimide precursor solution may be coated on the work table and the copper foils. Thereafter, the solution is imidized.

As illustrated in FIG. 3Ba, a plurality of p-type thermoelectric conversion patterns 32P are formed on the surface of the first flexible film 30 opposite to the surface where the first good thermal conductors 37 are fabricated. FIG. 3Bb is a cross sectional view taken along one-dot-chain line 3Bb-3Bb in FIG. 3Ba. Each p-type thermoelectric conversion pattern 32P is disposed in the thermoelectric generating part 34, and has a planar shape elongated in the longitudinal direction of the first flexible film 30. A plurality (three in FIG. 3Ba) of p-type thermoelectric conversion patterns 32P are disposed in the width direction of the first flexible film 30.

For example, chromel is used for the p-type thermoelectric conversion patterns 32P. Its film thickness is about 1 μm and width is 1 mm. The p-type thermoelectric conversion patterns 32P may be formed by sputtering using a metal mask 40 having openings corresponding to areas where the p-type thermoelectric conversion patterns 32P are to be formed.

As illustrated in FIG. 3Ca, a plurality of n-type thermoelectric conversion patterns 32N are formed on the surface of the first flexible film 30. FIG. 3Cb is a cross sectional view taken along one-dot chain line 3Cb-3Cb in FIG. 3Ca. Each n-type thermoelectric conversion pattern 32N has a planar shape almost the same as that of the p-type thermoelectric conversion pattern 32P, and is disposed between the p-type thermoelectric conversion patterns 32P.

For example, constantan is used for the n-type thermoelectric conversion patterns 32N. Its film thickness is about 1 μm. The n-type thermoelectric conversion patterns 32N may be formed by sputtering using a metal mask 41 having openings corresponding to areas where the n-type thermoelectric conversion patterns 32N are to be formed.

As illustrated in FIG. 3Da, a plurality of intra-layer wirings 27 and interlayer wirings 24 are formed on the first flexible film 30. FIG. 3Db is a cross sectional view taken along one-dot-chain line 3Db-3Db in FIG. 3Da. The intra-layer wring 27 interconnects the end portion of the n-type thermoelectric pattern 32N and the end portion of the p-type thermoelectric pattern 32P adjacent to each other in the width direction. In one thermoelectric generating part 34, one serial circuit is formed, the serial circuit having the n-type thermoelectric conversion patterns 32N and the p-type thermoelectric conversion patterns 32P alternately connected.

The interlayer wirings 24 interconnects the end portions of the serial circuits in adjacent thermoelectric generating parts 34. In FIG. 3Da, the end portions of the p-type thermoelectric generator patterns 32P are connected by the interlayer wiring 24. The interlayer wirings 24 serially connect the serial circuits formed in a plurality of thermoelectric generating parts 34.

For example, copper (Cu) is used for the interlayer wirings 24 and the intra-layer wirings 27, thicknesses of which are, e.g., about 0.3 μm. Silver (Ag) or aluminum (Al) may be used instead of copper. The interlayer wirings 24 and the intra-layer wirings 27 may be formed by sputtering using a metal mask 42 having openings corresponding to areas where the interlayer wirings 24 and the intra-layer wirings 27 are to be formed.

As illustrated in FIG. 3Ea and FIG. 3Eb, the second flexible film 31 is bonded to the first flexible film 30 with adhesive or the like. FIG. 3Eb is a cross sectional view taken along one-dot-chain line 3Eb-3Eb in FIG. 3Ea. The second flexible film 31 has almost the same planar shape as that of the first flexible film 30. The p-type thermoelectric conversion patterns 32P, the n-type thermoelectric conversion patterns 32N, the intra-layer wirings 27 and the interlayer wirings 24 are sandwiched between the first flexible film 30 and the second flexible film 31.

A second good thermal conductors 38 are being fabricated on the outer surface of the second flexible film 31. The second good thermal conductors 38 may be fabricated in the second flexible film 31 using the same method as that of fabricating the first good thermal conductors 37 in the first flexible film 30. A polyimide film having a thickness of, e.g., 50 μm is used for the second flexible film 31. Copper foils having a thickness of, e.g., 25 μm is used for the second good thermal conductors 38.

The second good thermal conductor 38 is disposed in the thermoelectric generating part 34 at a position displaced from the first good thermal conductor 37 in the longitudinal direction of the second flexible film 31 (at a position displaced to the right in FIG. 3Ea and FIG. 3Eb). Each of the p-type thermoelectric conversion patterns 32P and the n-type thermoelectric conversion patterns 32N extends from a position overlapping the first good thermal conductor 37 to a position overlapping the second good thermal conductor 38.

As illustrated in FIG. 3F, the first flexible film 30 and the second flexible film 31 are folded up by bending the films at the folded portions 33. By folding up the films, the thermoelectric parts 34 are superposed upon each other to form a five-layer stacked structure. Folded portions 33 appear on one side wall (left side wall in FIG. 3F), and other folded portions 33 appear on the opposite side wall (right side wall in FIG. 3F). The thermoelectric generating devices 20 are formed in the thermoelectric generating parts 34.

As illustrated in FIG. 2, three thermal conducting members 21 are connected to the first thermal coupling member 22, and three thermal conducting members 21 are connected to the second thermal coupling member 23. For these connecting, a method not preventing thermal conduction, such as welding, is applied. A steel plate having a thickness of, e.g., 100 μm is used for the thermal conducting member 21. An aluminum plate, a silver plate or the like may be used instead of the steel plate. The thermal conducting members 21 connected to the first thermal coupling member 22 are inserted between the thermoelectric generating devices 20 from one side wall (left side wall in FIG. 2) on which the folded portions 33 appear. The thermal conducting members 21 connected to the second thermal coupling member 23 are inserted between the thermoelectric generating devices 20 from the other side wall (right side wall in FIG. 2) on which the folded portions 33 appear.

The first good thermal conductors 37 are in contact with the thermal conducting members 21 connected to the second thermal coupling member 23, and the second good thermal conductors 38 are in contact with the thermal conducting members 21 connected to the first thermal coupling member 22. For example, the outermost (lowermost in FIG. 2) thermal conducting member 21 connected to the first thermal coupling member 22 is in contact with a higher temperature portion, and the outermost (uppermost in FIG. 2) thermal conducting member 21 connected to the second thermal coupling member 23 is in contact with a lower temperature portion.

A thermal conductivity of the first thermal coupling member 22, the second thermal coupling member 23 and the thermal conducting members 21 is higher than that of the first flexible film 30 and the second flexible film 31. The thermal conducting members 21 connected to the first thermal coupling member 22 take therefore a higher temperature than the thermal conducting members 21 connected to the second thermal coupling member 23. A thermal conductivity of the first good thermal conductor 37 and the second good thermal conductor 38 is higher than that of the first flexible film 30 and the second flexible film 31. A thermal path is therefore formed from the higher temperature thermal conducting members 21 to the lower temperature thermal conducting members 21 via the second good thermal conductor 38, the second flexible film 31, the first flexible film 30 and the first good thermal conductor 37. A temperature gradient lowering a temperature from the second good thermal conductor 38 toward the first good thermal conductor 37 is generated in each thermoelectric generating device 20. Each of the first good thermal conductors 37 and the second good thermal conductors 38 generates a temperature difference in the in-plane direction from a temperature difference in the thickness direction of the thermoelectric generating device 20.

As an in-plane temperature difference is generated, temperature difference in a longitudinal direction is generated in each of the p-type thermoelectric conversion patterns 32P and the n-type thermoelectric conversion patterns 32N. This temperature difference generates a thermoelectromotive force due to the thermoelectric effects. As in the case of the first embodiment, the thermoelectric generator of the second embodiment is able to improve an electric power generation ability per unit area.

An in-plane direction displacement amount of the first good thermal conductor 37 and the second good thermal conductor 38 is set so that a temperature difference in the in-plane direction is generated efficiently. For example, the first good thermal conductor 37 and the second good thermal conductor 38 are disposed in such a manner that vertical projected images of the first good thermal conductor 37 and the second good thermal conductor 38 onto a virtual flat plane perpendicular to the stacked direction are not overlapped with each other. The first good thermal conductor 37 and the second good thermal conductor 38 may be disposed in such a manner that edges facing to each other of the vertical projected images of the first good thermal conductor 37 and the second good thermal conductor 38 become coincident.

The thermoelectric generator of the second embodiment has a multi-layer structure having a plurality of thermoelectric generating devices 20 which are stacked. The interlayer wirings 24 electrically interconnecting the thermoelectric generating devices 20 are formed at the same time when the intra-layer wirings 27 in one thermoelectric generating device 20 are formed in the process illustrated in FIG. 3Da and FIG. 3Db. The manufacture processes are able to be simplified more than the method of interconnecting the thermoelectric generating devices 20 after a plurality of thermoelectric generating devices 20 are stacked.

Next, description will be made on the reliability of the folded portions 33. As a curvature of the folded portion 33 is made small, it is apprehended that the reliability lowers. In the second embodiment, design was performed on the basis of R=0.38 mm in conformity with the specifications of a flexible print board, JIS C5016 Folding Endurance Test. Raw material for the flexible film adopted satisfies the criterion of the number of bending times of 70 or more under the conditions of a bending angle of 135° and a bending speed of 170 times/min. The thermoelectric generator of the second embodiment will not be bent repetitively during use after it is bend once during manufacture. It is therefore possible to maintain sufficient reliability by using a flexible film satisfying the above-described criterion.

Since the first thermal coupling member 22 and the second thermal coupling member 23 are disposed outside the folded portions 33, it is possible to prevent an external force from directly acting upon the folded portions 33. It is therefore possible to suppress wearing and the like of the folded portions 33 to be caused by an external force.

Further, the thermoelectric generator of the second embodiment does not have the structure of hindering curvature of the thermoelectric generator, in a direction (horizontal direction in FIG. 2) from one side wall on which the folded portions 33 appear toward the other side wall. The thermoelectric generator has therefore high flexibility in the horizontal direction (easy curvature direction) in FIG. 2. If the surface of a heat generator has a cylindrical shape, a thermoelectric generator is able to be curved along the cylindrical surface by aligning the easy curvature direction with a cylindrical surface curvature direction.

In the second embodiment, although chromel and constantan are used as the thermoelectric conversion material, other materials may also be used. It is possible to use, e.g., BiTe based material, PbTe based material, Si—Ge based material, silicide based material, skutterudite based material, transition metal oxide based material, zinc antimonide based material, boron compound, cluster solid, zinc oxide based material, carbon nanotube and the like.

Examples of the BiTe based material include BiTe, SbTe, BiSe and their compounds. Examples of the PbTe based material include PbTe, SnTe, AgSbTe, GeTe and their compounds. Examples of the Si—Ge based material include Si, Ge, SiGe and the like. Examples of the silicide based material include FeSi, MnSi, CrSi and the like. Examples of the sutterudite based material is represented by a general expression MX3 or RM4X12 where M represents Co, Rh or Jr, X represents As, P or Sb, and R represents La, Yb, or Ce. Examples of the transition metal oxide material include NaCoO, CaCoO, ZnInO, SrTiO, BiSrCoO, PbSrCoO, CaBiCoO, BaBiCoO and the like. An example of the zinc antimonide based material includes ZnSb. Examples of the boron compound include CeB, BaB, SrB, CaB, MgB, VB, NiB, CuB, LiB and the like. Examples of the cluster solid include B cluster, Si cluster, C cluster, AlRe, AlReSi and the like. An example of the zinc oxide based material includes ZnO.

### Third Embodiment

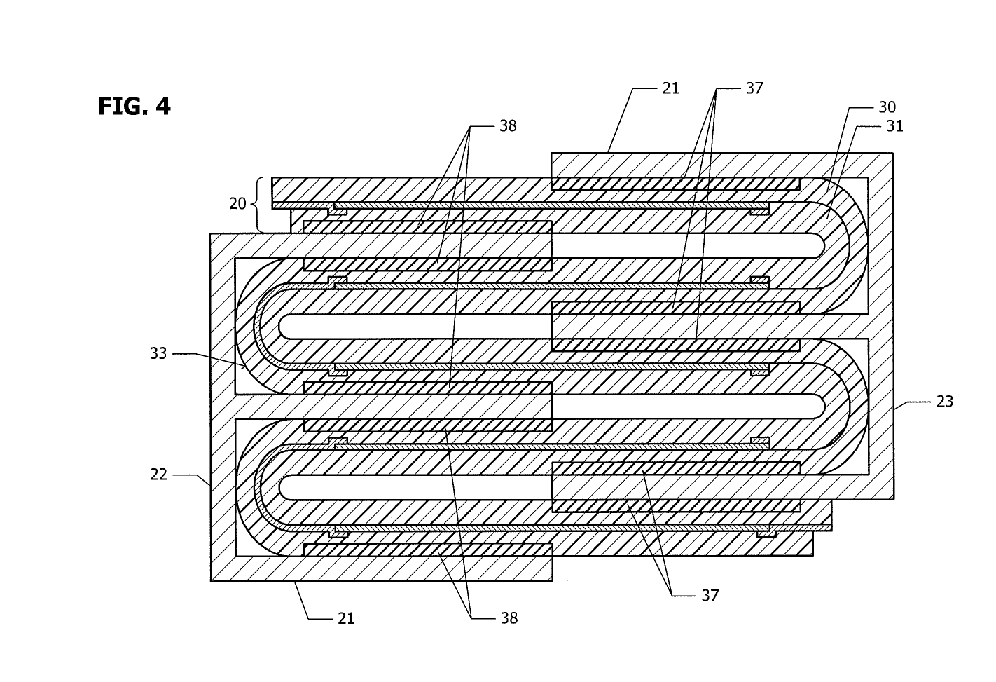

FIG. 4 is a cross sectional view illustrating the thermoelectric generator of the third embodiment. In the following description, different points from the thermoelectric generator of the second embodiment illustrated in FIG. 2 are paid attention, and duplicative description of the same structures as those of the second embodiment is omitted.

In the second embodiment, in all thermoelectric generating parts 34, the second good thermal conductor 38 is displaced from the first good thermal conductor 37 toward the same side. In the state that the first flexible film 30 and the second flexible film 31 are folded, a direction from the first good thermal conductor 37 toward the second good thermal conductor 38 in the thermoelectric generating device 20 is opposite to that in the adjacent thermoelectric generating device 20.

In the third embodiment, as illustrated in FIG. 4, in the folded state, in all the thermoelectric generating devices 20, the second good thermal conductor 38 is displaced from the first good thermal conductor 37 toward the same side (left side in FIG. 4). More specifically, in the thermoelectric generating device 20, the first good thermal conductor 37 is located off-center toward the second thermal coupling member 23, and the second good thermal conductor 38 is located off-center toward the first thermal coupling member 22.

It is sufficient that the thermal conducting members 21 connected to the first thermal coupling member 22 are inserted to a depth in such a manner that the thermal conducting members 21 are in contact with the second good thermal conductor 38. Similarly, it is sufficient that the thermal conducting members 21 connected to the second thermal coupling member 23 is inserted to a depth in such a manner that the thermal conducting members 21 are in contact with the first good thermal conductor 37.

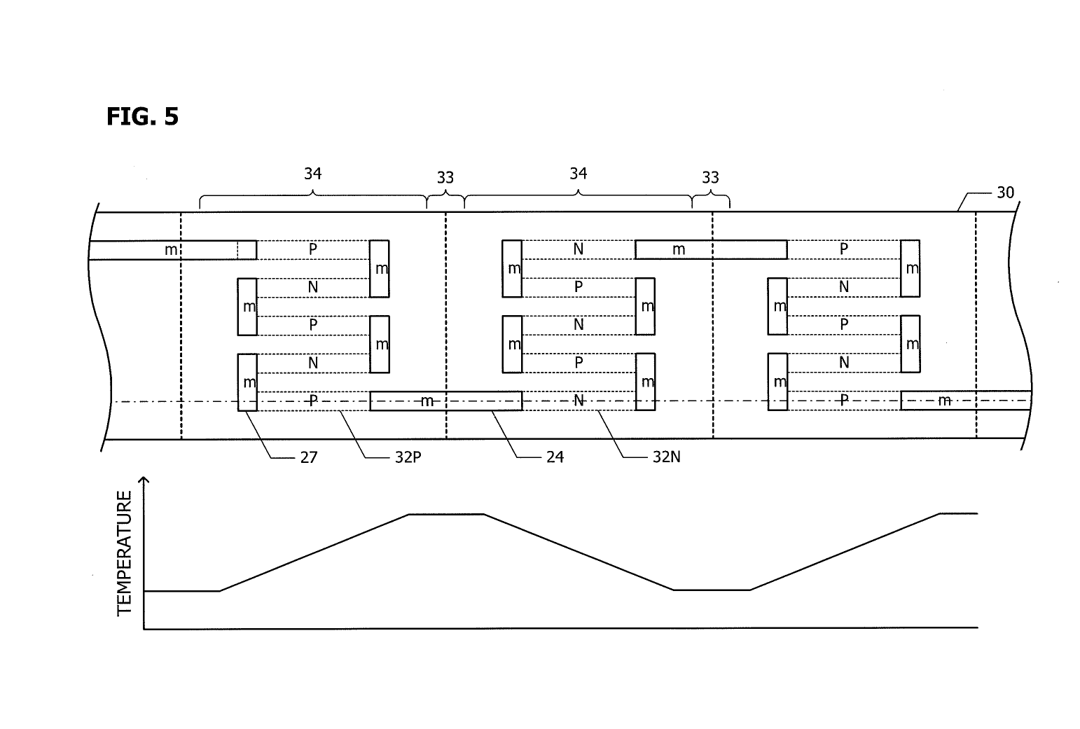

FIG. 5 is a developed planar view of the first flexible film 30. In the second embodiment, as illustrated in FIG. 3Da, the interlayer insulating wirings 24 interconnects the p-type thermoelectric conversion patterns 32P together. In the third embodiment, the interlayer wirings 24 connects the p-type thermoelectric conversion pattern 32P in one thermoelectric generating part 34 to the n-type thermoelectric conversion pattern 32N in the other thermoelectric generating part 34.

An example of a temperature distribution is illustrated in a lower area of FIG. 5. One of the folded portions 33 adjacent to each other takes a high temperature, and the other takes a low temperature. In the thermoelectric generating part 34, a temperature gradually lowers from the high temperature folded portion 33 toward the low temperature folded portion 33.

In the third embodiment, an insertion depth of the thermal conducting member 21 is possible to be shallower than that of the second embodiment as illustrated in FIG. 4. It is therefore possible for the structure of the third embodiment to reduce material to be used, and trim weight of the generator. It is also possible to efficiently generate a temperature difference in the in-plane direction compared to the structure of the second embodiment.

### Fourth Embodiment

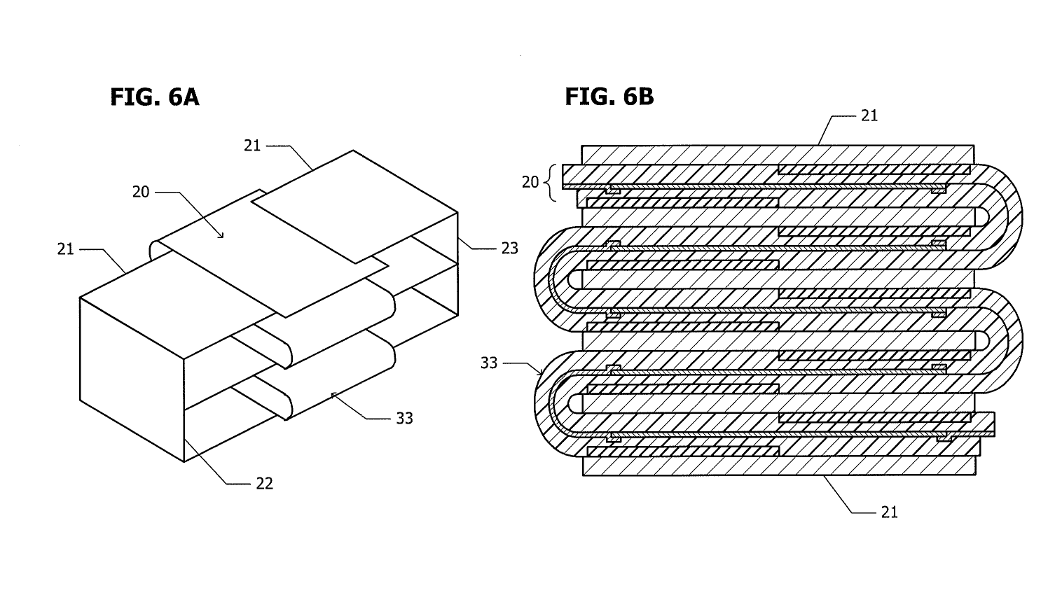

FIG. 6A and FIG. 6B are a broken perspective view and a cross sectional view of a thermoelectric generator of the fourth embodiment, respectively. Next, description will be made by paying attention to the different points from the thermoelectric generator of the second embodiment illustrated in FIG. 2. Duplicative description of the same structures as those of the second embodiment is omitted.

In the second embodiment, the thermal conducting members 21 are inserted between the thermoelectric generating devices 20 from the side wall on which the folded portions 33 appear. In the fourth embodiment, the thermal conducting members 21 are inserted between the thermoelectric generating devices 20 from side walls adjacent to the side walls on which the folded portions 33 appear. Also in the fourth embodiment, an electric power generation ability per unit area can be improved as in the case of the second embodiment.

The thermoelectric generator of the second embodiment has high flexibility in a direction (easy curvature direction) from one side wall on which the folded portions 33 appears toward the other side wall. On the other hand, in the direction perpendicular to the easy curvature direction, flexibility is low because the folded portions 33, the first thermal coupling members 22 and the second thermal coupling members 23 hinder bending the stacked structure. In the fourth embodiment, this bending feasibility is less dependent upon directivity because the side walls on which the folded portions 33 appear are different from the side walls along which the first thermal coupling member 22 and the second thermal coupling member 23 are disposed.

### Fifth Embodiment

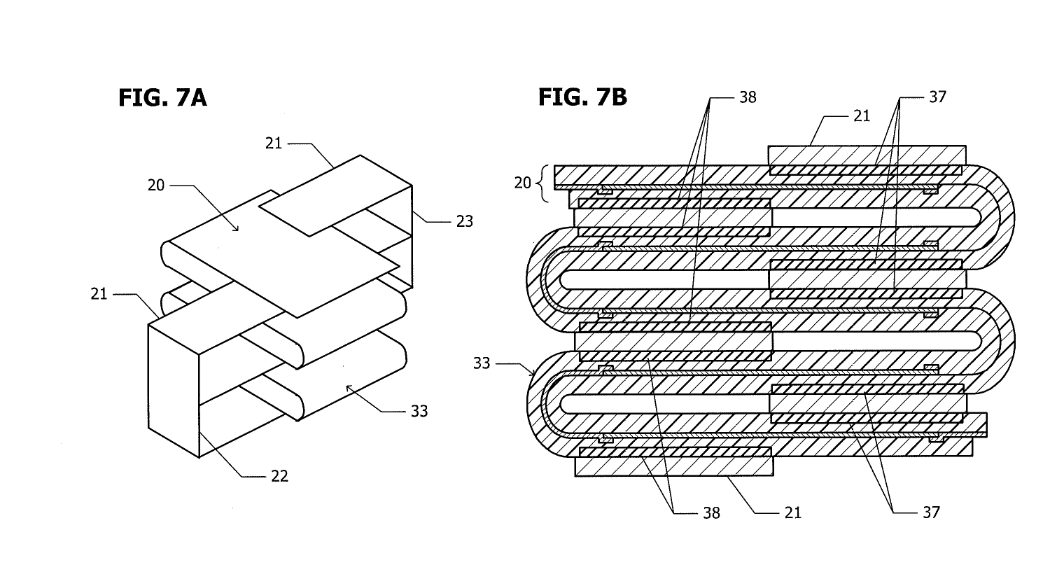

FIG. 7A and FIG. 7B are a broken perspective view and a cross sectional view of a thermoelectric generator of the fifth embodiment. Next, description will be made by paying attention to the different points from the thermoelectric generator of the fourth embodiment illustrated in FIG. 6. Duplicative description of the same structures as those of the fourth embodiment is omitted.

In the fourth embodiment, as in the case of the second embodiment, temperature gradients in the in-plane direction in the thermoelectric generating devices 20 are opposite to each other in two adjacent thermoelectric generating devices 20 in the stacked direction. In the fifth embodiment, as in the case of the third embodiment, in all the thermoelectric generating devices 20, the direction of the temperature gradient is the same. More specifically, as illustrated in FIG. 7B, in all the thermoelectric generating devices 20, an in-plane direction from the first good thermal conductor 37 toward the second good thermal conductor 38 is the same (left-pointing direction in FIG. 7B).

The thermal conducting members 21 connected to the first thermal coupling member 22 have a size sufficient for being in contact with the second good thermal conductor 38, and does not disposed in the whole in-plane are of the thermoelectric generating device 20. Similarly, the thermal conducting members 21 connected to the second thermal coupling member 23 have a size sufficient for being in contact with the first good thermal conductor 37, and does not disposed in the whole in-plane are of the thermoelectric generating device 20. As compared to the thermoelectric generator of the fourth embodiment, it is possible to reduce the volume of the first thermal coupling member 22, the second thermal coupling member 23 and the thermal conducting members 21. It is also possible to efficiently generate a temperature difference in the in-plane direction as in the case of the third embodiment.

### Sixth Embodiment

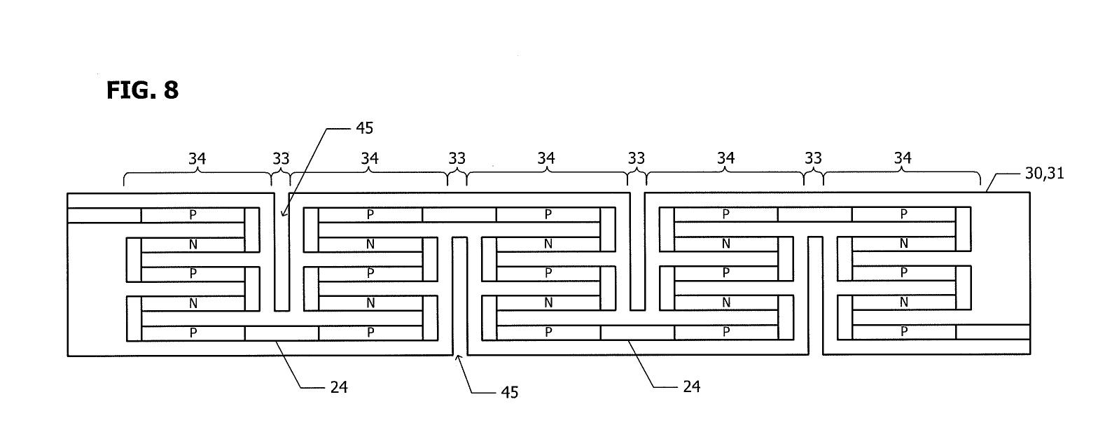

FIG. 8 is a developed planar view of the first flexible film 30 and the second flexible film 31 to be used for the thermoelectric generator of the sixth embodiment. Description will be made by paying attention to the different points from the thermoelectric generator of the second embodiment illustrated in FIG. 2. Duplicative description of the same structures as those of the second embodiment is omitted.

In the sixth embodiment, slits 45 are formed is the folded portions 33 of the first flexible film 30 and the second flexible film 31, and in areas where the interlayer wirings 24 are not formed. The structure in the thermoelectric generating parts 34 are the same as that of the second embodiment. Namely, a width of the folded portion 33 of the first flexible film 30 and the second flexible film 31 is narrower than a width of the thermoelectric generating part 34. The slits 45 may be formed after the first flexible film 30 and the second flexible film 31 are bonded, or the a first flexible film 30 and the a second flexible film 31 each having slits 45 in advance may be used.

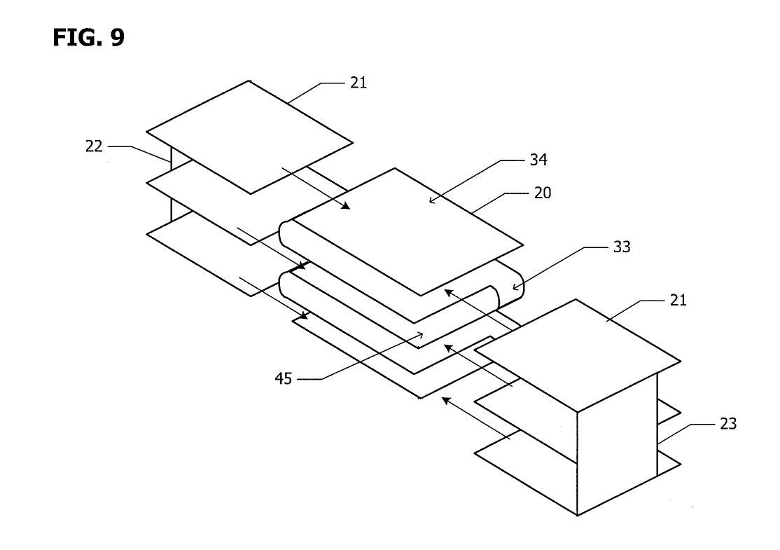

FIG. 9 is a broken perspective view of the thermoelectric generator of the sixth embodiment. The first thermal coupling member 22 is disposed along one side wall on which the folded portions 33 appear (back left side in FIG. 9), and the second thermal coupling member 23 is disposed along the other side wall on which the folded portions 33 appear (front right side in FIG. 9). At least a portion of the first thermal coupling member 22 and at least a portion of the second thermal coupling member 23 are disposed within the width of the thermoelectric generating parts 34. The first thermal coupling portion 22 is not disposed within a width of the folded portions 33 appearing on the corresponding side wall. Namely, the first thermal coupling member 22 is disposed at a position escaping the folded portions 33. Similarly, the second thermal coupling portion 23 is not disposed within a width of the folded portions 33 appearing on the corresponding side wall.

In the sixth embodiment, at the side wall on which the folded portions 33 appears, the folded portions 33 and the first thermal coupling member 22 are not be overlapped to each other, and the folded portions 33 and the second thermal coupling member 23 are not be overlapped to each other. Flexibility of the side wall on which the folded portions 33 appear is therefore improved so that the thermoelectric generator is easy to be bended in a direction perpendicular to a direction from one side wall on which the folded portions 33 appear toward the other side wall. It is also possible to trim weight of the thermoelectric generator.

### Seventh Embodiment

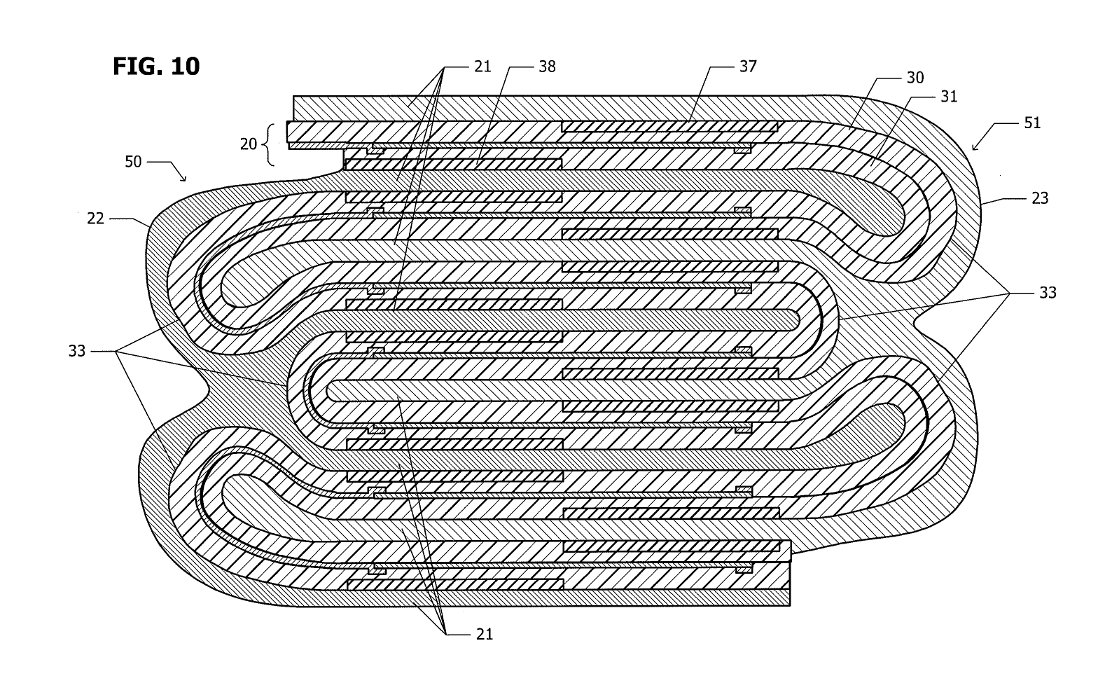

FIG. 10 is a cross sectional view of a thermoelectric generator of the seventh embodiment. Description will be made by paying attention to the different points from the thermoelectric generator of the second embodiment illustrated in FIG. 2. Duplicative description of the same structures as those of the second embodiment is omitted.

In the second embodiment, the folded portions 33 are superimposed in the stacked direction, and disposed at the same position in the in-plane direction. In the seventh embodiment, two adjacent folded portions 33 in the stacked direction are displaced in the in-plane direction (lateral direction in FIG. 10). By displacing the folded portions 33 in the in-plane direction, it is possible to increase a radius of curvature of the folded portions 33.

In the second embodiment, metal plates are used as the first thermal coupling member 22, the second thermal coupling member 23 and the thermal conducting members 21. In the seventh embodiment, material obtained by solidifying conductive paste, e.g., silver (Ag) paste is used. Description will be made on a manufacture method for the thermoelectric generator.

In a state (a state illustrated in FIG. 3Eb) that the second flexible film 31 is bonded to the first flexible film 20, Ag paste is coated on the outer surfaces of the first flexible film 30 and the second flexible film 31. Before the coated Ag paste is solidified, the first flexible film 30 and the second flexible film 31 are folded up. As the films are folded up, the structure that the Ag paste is filled between the thermoelectric elements 20 is obtained. The outer surfaces of the outermost thermoelectric generating devices 20 in the stacked direction and the outer surfaces of the folded portions 33 are in the state that the surfaces are covered with Ag paste.

In this state, the Ag paste is solidified by performing a heat process for about 30 minutes at a temperature of, e.g., 200° C. As the Ag paste is solidified, a thermal conducting film 51 covering the surface of the first flexible film 30 and a thermal conducting film 50 covering the surface of the second flexible film 31 are formed. The thermal conducting films 50 and 51 obtained through solidification of the Ag paste have a higher thermal conductivity than that of the first flexible film 30 and the second flexible film 31. A portion of the thermal conducting films 50 and 51 disposed between the thermoelectric generating devices 20 serves as the thermal conducting member 21 of the second embodiment illustrated in FIG. 2. A portion covering the folded portions 33 serves as the first thermal coupling member 22 and the second thermal coupling member 23.

The Ag paste coated on the first flexible film 30 and the second flexible film 31 easily deforms as the flexible films are deformed. It is therefore easy to manufacture even a thermoelectric generator of a complicated shape displacing the positions of the folded portions 33 in the in-plane direction. Even in the complicated shape, high Light contact between the first good thermal conductor 37 and the thermal conducting film 51 and high tight contact between the second good thermal conductor 38 and the thermal conducting film 50 are able to be maintained.

### Eighth Embodiment

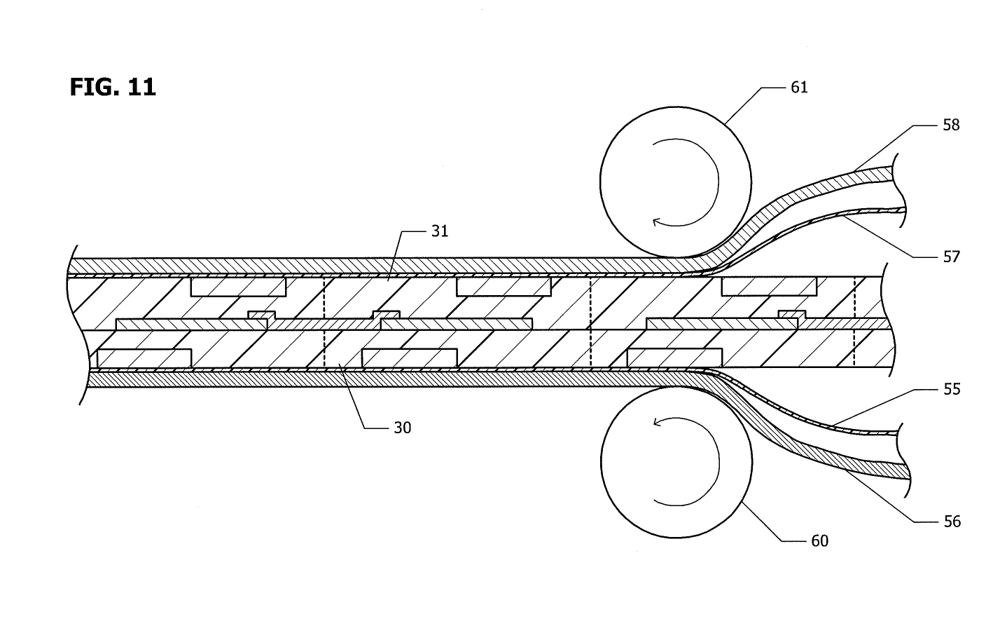

FIG. 11 is a cross sectional view illustrating a thermoelectric generator of the eighth embodiment at an intermediate stage of manufacture. Description will be made by paying attention to the different points from the thermoelectric generator of the second embodiment illustrated in FIG. 2. Duplicative description of the same structures as those of the second embodiment is omitted.

After the second flexible film 31 is bonded to the first flexible film 30 (after the state illustrated in FIG. 3Eb of the second embodiment), a thermal conducting film 56 made of material having a high thermal conductivity such as copper is bonded on the outer surface of the first flexible film 30 using an two-sided adhesive sheet 55. Similarly, a thermal conducting film 58 is bonded on the outer surface of the second flexible film 31 using an two-sided adhesive sheet 57. In bonding the thermal conducting films 56 and 58, a pressure bonding method using a pair of roles 60 and 61 may be adopted. Instead, a heating adhesion method using heating adhesive may also be used. The thermal conducting films 56 and 58 are able to be deformed depending upon deformation of the first flexible film 30 and the second flexible film 31.

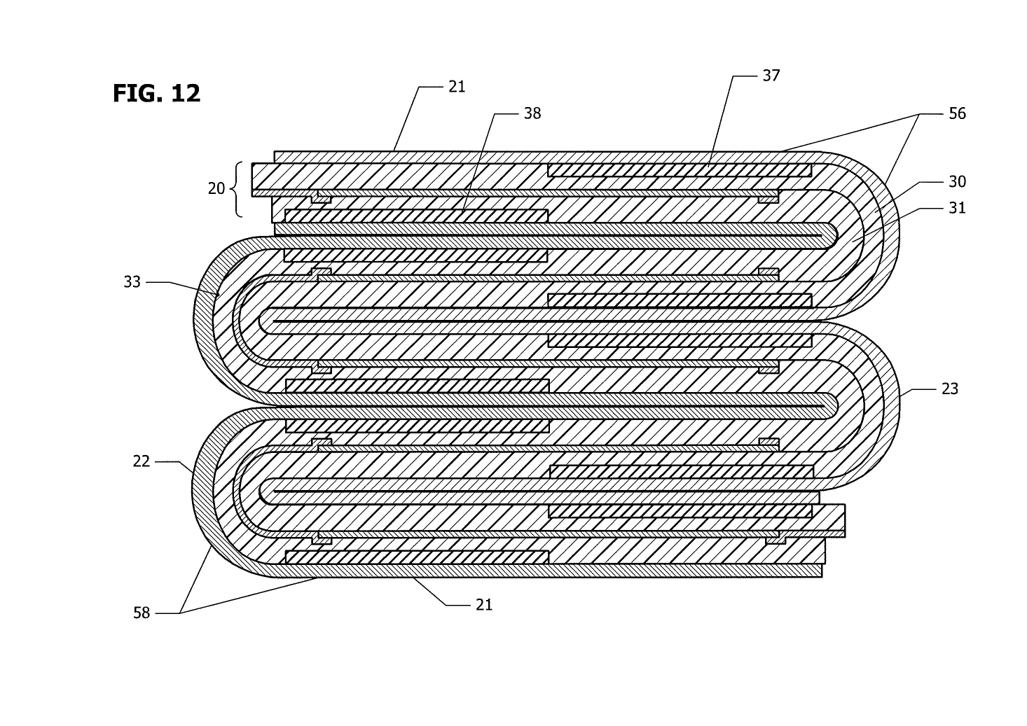

As illustrated in FIG. 12, the first flexible film 30 and the second flexible film 31 bonded with the thermal conducting films 56 and 58 are folded up. Different portions of the thermal conducting film 56 are made in tight contact with each other, the different portions being located between two portions of the first flexible film 30 facing each other. Similarly, different portions of the thermal conducting film 58 are made in tight contact with each other, the different portions being located between two portions of the second flexible film 31 facing each other. Adhesive may be used to improve tight contact between the different portions of the thermal conducting film 56 and between the different portions of the thermal conducting film 58.

Portions of the thermal conducting films 56 and 58 sandwiched between the thermoelectric generating devices 20 serve as the thermal conducting members 21 illustrated in FIG. 2. Portions of the thermal conducting films 56 and 58 covering the outer surfaces of the folded portions 33 serve as the second thermal coupling member 23 and the first thermal coupling member 22, respectively.

In the thermoelectric generating device of the eighth embodiment, a mounting process for the thermal conducting members 21 and the like is not required to be executed after the first flexible film 30 and the second flexible film 31 are folded up.

### Ninth Embodiment

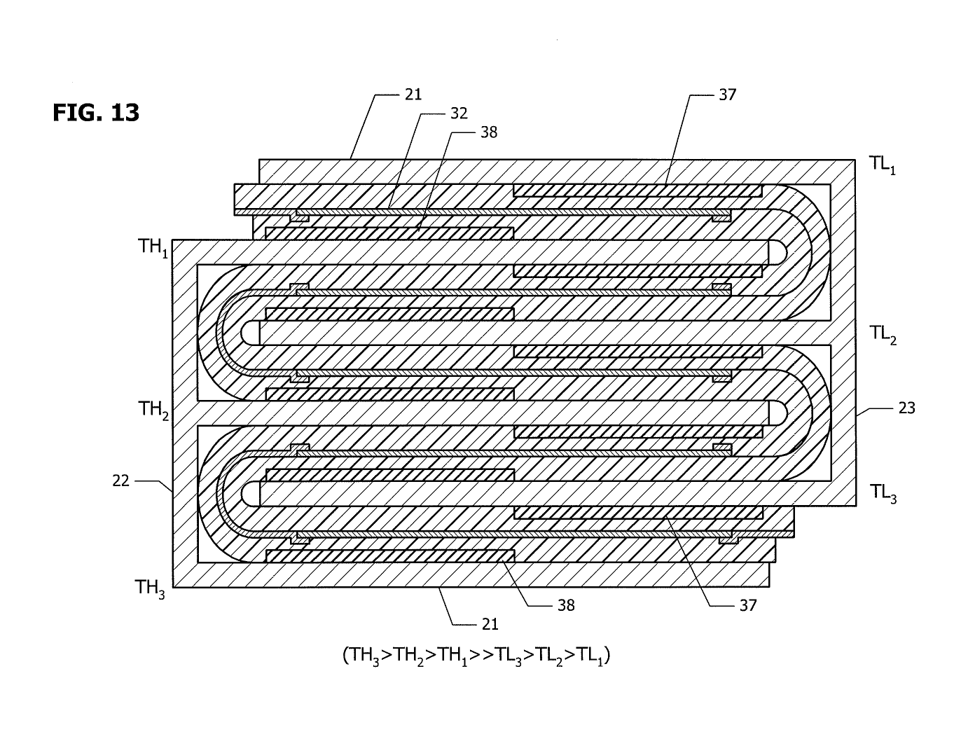

FIG. 13 is a cross sectional view of a thermoelectric generator of the ninth embodiment. Description will be made by paying attention to the different points from the thermoelectric generator of the second embodiment illustrated in FIG. 2. Duplicative description of the same structures as those of the second embodiment is omitted.

In the second embodiment, a plurality of p-type thermoelectric conversion patterns 32P illustrated in FIG. 3Da and the like are all made of the same thermoelectric conversion material, and a plurality of n-type thermoelectric conversion patterns 32N are also all made of the same thermoelectric conversion material. In the ninth embodiment, the material or composition of the p-type thermoelectric conversion patterns 32P and the n-type thermoelectric conversion patterns 32N is different for each of thermoelectric generating devices 20.

Consider for example the case in which the lowermost thermal conducting member 21 of the stacked structure illustrated in FIG. 13 takes the highest temperature, and the uppermost thermal conducting member 21 takes the lowest temperature. Although the first thermal coupling member 22 and the thermal conducting members 21 are made of good thermal conductor, a thermal conductivity is not infinite. The temperatures of the thermal conducting members 21 coupled to the first thermal coupling member 22 are therefore not the same, but the temperature lowers from the lower side toward the upper side. As the temperatures of the thermal conducting members 21 coupled to the first thermal coupling member 22 are represented by TH₃, TH₂ and TH₁ sequentially from the lower side, an inequality of TH₃>TH₂>TH₁ is satisfied. As the temperatures of the thermal conducting members 21 coupled to the second thermal coupling member 23 are represented by TL₁, TL₂ and TL₃ sequentially from the upper side, an inequality of TL₃>TL₂>TL₁ is satisfied. A temperature TH₁ is sufficiently higher than TL₃.

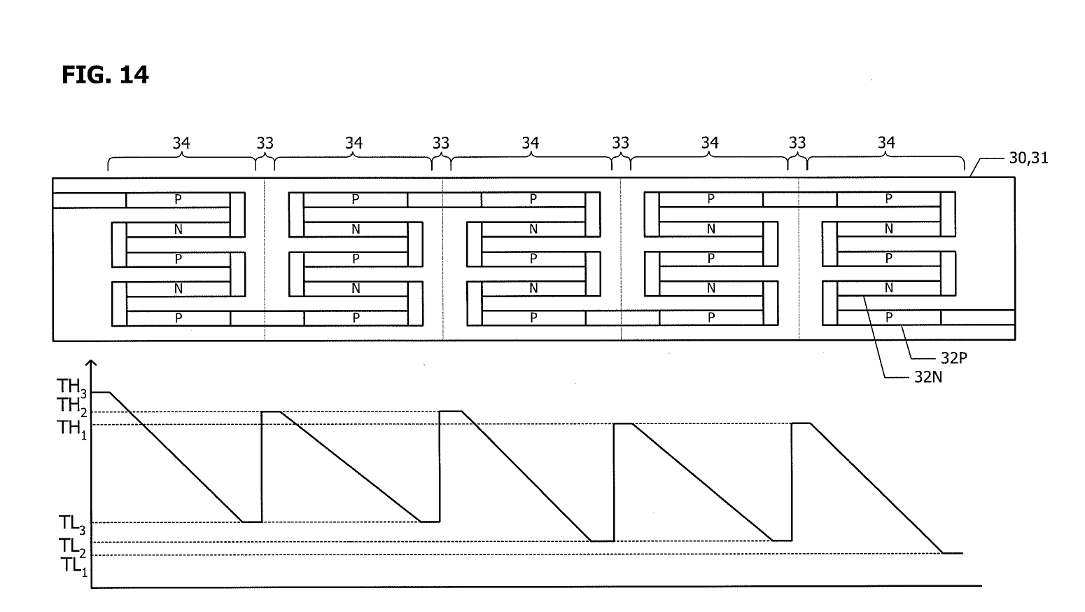

FIG. 14 is a developed planar view of the first flexible film 30 and the second flexible film 31. An example of the temperature distribution is illustrated under the developed planar view. In FIG. 14, there is a temperature difference between opposite ends of each of the p-type thermoelectric conversion patterns 32P and each of the n-type thermoelectric conversion patterns 32N formed in the leftmost side thermoelectric generating part 34, to be caused by a temperature difference TH₃-TL₃ in the thickness direction. There are temperature differences between opposite ends of each of the p-type thermoelectric conversion patterns 32P and each of the n-type thermoelectric conversion patterns 32N formed in the second to fifth thermoelectric generating parts 34 from the left side, to be caused by temperature differences TH₂-TL₃, TH₂-TL₂, TH₁-TL₂ and TH₁-TL₁, respectively.

A thermoelectric conversion efficiency of thermoelectric conversion material generally depends on an operating temperature. As illustrated in FIG. 14, operating temperatures of a plurality of the thermoelectric generating devices 20 are different from each other. In the ninth embodiment, the p-type thermoelectric conversion patterns 32P and the n-type thermoelectric conversion patterns 32N constituting the thermoelectric generating devices 20 are made of material most suitable for the operating temperatures. For this constitution, the p-type thermoelectric conversion patterns 32P and the n-type thermoelectric conversion patterns 32n are formed by different film forming processes for each thermoelectric generating part 34.

For example, an optimum operating temperature of n-type thermoelectric conversion material doped with Se, namely (Bi₂Te₃)_{0.95} (Bi₂Se₃)_{0.05}, is about 300 K. An optimum operating temperature of n-type thermoelectric conversion material doped with Se, namely (Bi_{0.7}Te_{0.3})₂Te₃, is about 220 K. An optimum operating temperature of p-type thermoelectric conversion material doped with Sb, namely (Bi₂Te₃)_{0.25} (Sb₂Te₃)_{0.75} is equal to or higher than 340 K. An optimum operating temperature of p-type thermoelectric conversion material doped with Sb and Se, namely Bi_{0.8}Sb_{1.2}Te₃+7% Bi₂Se₃ is about 240 K. An optimum operating temperature is able to be adjusted by adjusting a composition, dopant, a dopant concentration and the like of the thermoelectric conversion material. The optimum operating temperature means an average temperature between high temperature end and low temperature end.

In the ninth embodiment, a suitable thermoelectric conversion material is selected in accordance with an operating temperature of each layer. It is therefore possible to improve an electric power generation efficiency.

### Tenth Embodiment

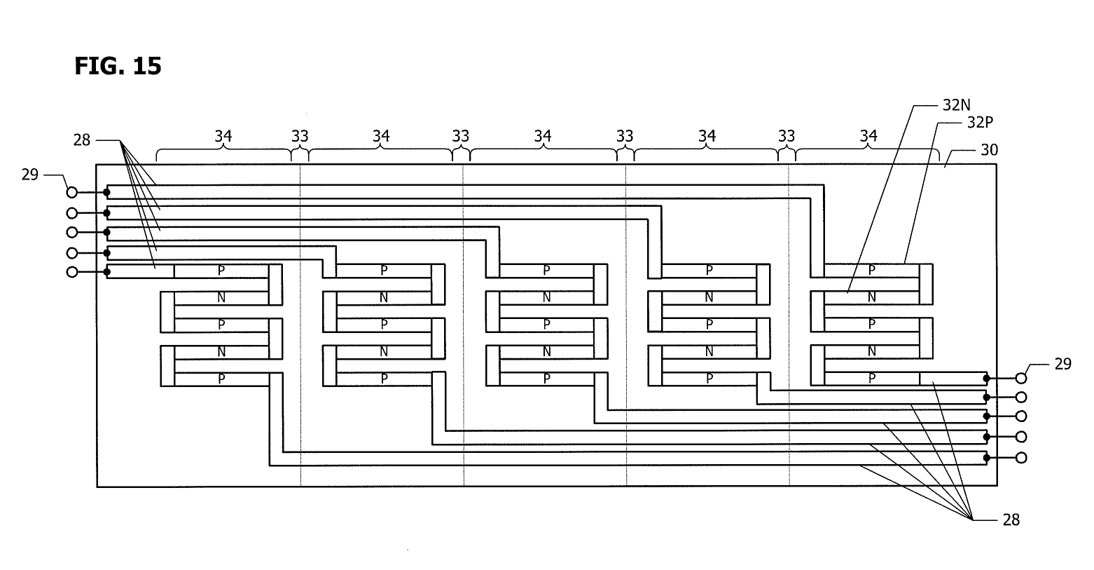

FIG. 15 is a developed planar view of the first flexible film 30 of the thermoelectric generator of the tenth embodiment. Description will be made by paying attention to the different points from the thermoelectric generator of the second embodiment illustrated in FIG. 2. Duplicative description of the same structures as those of the second embodiment is omitted.

In the thermoelectric generator of the second embodiment, as illustrated in FIG. 3Ea, the interlayer wirings 24 interconnects the circuits in adjacent thermoelectric generating parts 34. In the tenth embodiment, the circuit in each of the thermoelectric generating parts 34 is lead to an external terminal 29 by a lead wiring 28.

In the tenth embodiment, by interconnecting the external terminals 29, the circuits in the thermoelectric generating parts 34 may be connected in series or in parallel. If the circuit in one thermoelectric generating part 34 is broken, only the circuits in other good thermoelectric generating parts 34 may be connected excluding the circuit in the broken thermoelectric generating part 34.

### Eleventh Embodiment

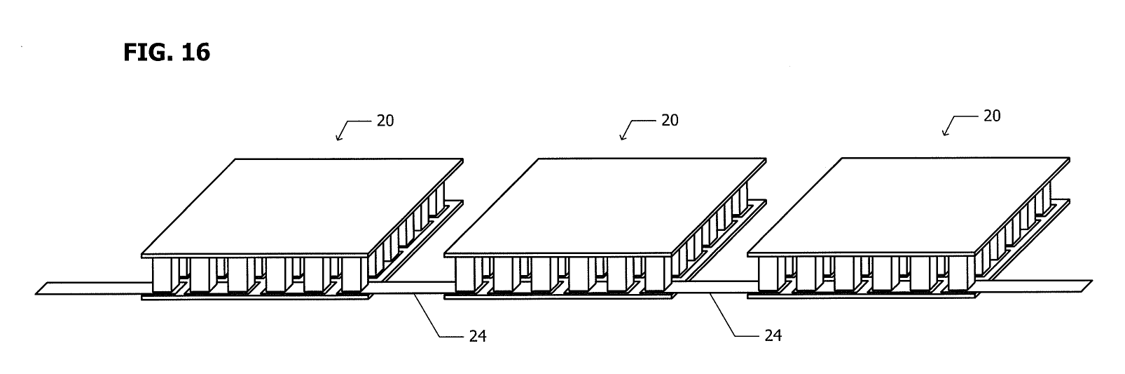

FIG. 16 is a developed perspective view of a thermoelectric generator of the eleventh embodiment. The thermoelectric generator of the eleventh embodiment includes a plurality of thermoelectric generating devices 20. each thermoelectric generating device 20 is an assembly of so-called n (pi) type thermoelectric conversion elements and generates an electric power when a temperature difference is generated in the thickness direction. The interlayer wiring 24 interconnects a plurality of thermoelectric generating devices 20 in series. For example, a flexible printed circuit (FPC) board may be used for the interlayer wiring 24.

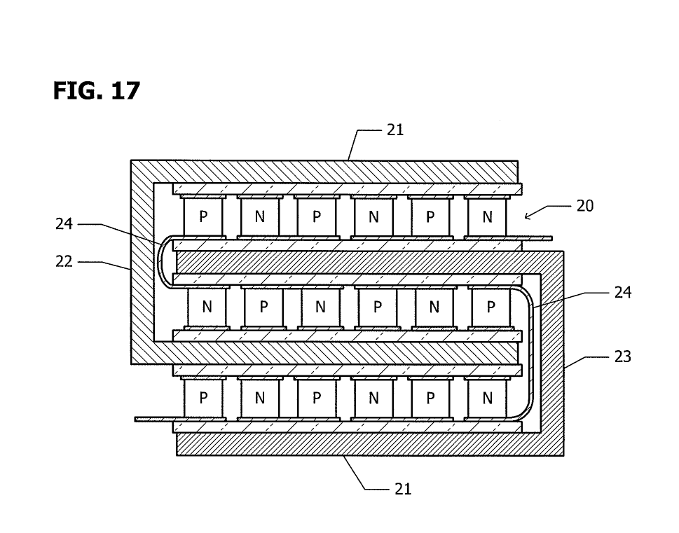

FIG. 17 is a cross sectional view of a thermoelectric generator of the eleventh embodiment. Plate-shape thermoelectric generating devices 20 are stacked. The thermoelectric generating devices 20 adjacent in a stacked direction are interconnected by the interlayer wiring 24. A thermal conducting member 21 is inserted between the thermoelectric generating devices 20. The thermal conducting members 21 are in contact with also the outer surfaces of the outermost thermoelectric generating devices 20 in the stacked direction.

The first thermal coupling member 22 is connected to every other thermal conducting members 21. A second thermal coupling member 23 is connected to the thermal conducting members 21 not connected to the first thermal coupling member 22.

Also in the eleventh embodiment, an electric power generation efficiency per unit area is able to be improved as in the case of the first to tenth embodiments.

### Twelfth Embodiment

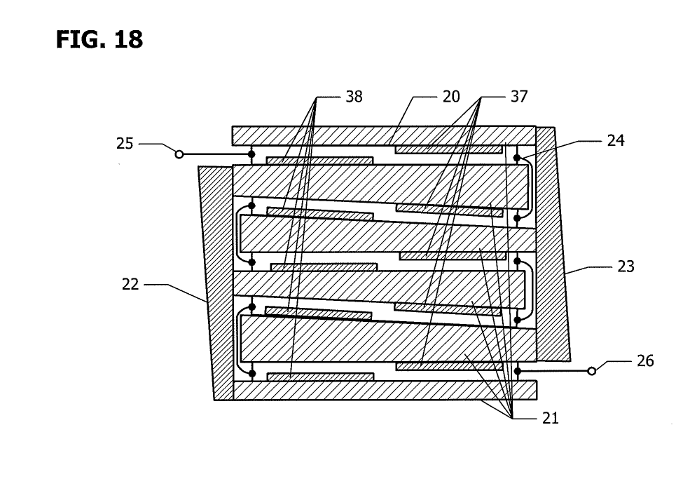

FIG. 18 is a cross sectional view of the thermoelectric generator of the twelfth embodiment. Description will be made by paying attention to the different points from the thermoelectric generator of the first embodiment illustrated in FIG. 1. Duplicative description of the same structures as those of the first embodiment is omitted.

In the first embodiment, a thickness of each of the thermal conducting members 21, the first thermal coupling member 22 and the second thermal coupling members 23 is uniform. In the twelfth embodiment, both of the first thermal coupling member 22 and the second thermal coupling member 23 are made gradually thicker with distance from the end portion connected to the outermost thermal conducting member 21. For example, in FIG. 18, if the lowermost thermal conducting member 21 is coupled to a heat generation source, the first thermal coupling member 22 is made gradually thicker with distance from the heat generation source. The second thermal coupling member 23 is made gradually thicker with distance from a heat absorber such as a heat sink.

Namely, a cross sectional area of a thermal path constituted of the first thermal coupling member 22 becomes larger toward a first side in a stacked direction (upward in FIG. 18). A cross sectional area of a thermal path constituted of the second thermal coupling member 23 becomes larger toward a second side opposite to the first side in the stacked direction (downward in FIG. 18).

The layout of the first good thermal conductors 37 and the second good thermal conductors 38 is the same as the layout of the second embodiment illustrated in FIG. 2.

A temperature of the first thermal coupling member 22 is highest at the position connected to the lowermost thermal conducting member 21 directly coupled to the heat generation source, and gradually lowers with distance from this connected position. A temperature of the second thermal coupling member 23 is lowest at the position connected to the uppermost thermal conducting member 21 directly coupled to the heat absorber, and gradually rises with distance from this connected position.

In the twelfth embodiment, a cross sectional area of a thermal path constituted of the first thermal coupling member 22 becomes larger with distance from the heat generation source. As the cross sectional area becomes larger, a thermal resistance lowers. A temperature distribution slope of the first thermal coupling member 22 is able to be made smaller particularly in a portion remoter from the heat generation source and a portion where heat from the heat generation source is hard to be transferred. Similarly, a temperature distribution slope of the second thermal coupling member 23 is able to be made smaller in a portion remoter from the heat absorber and a portion where a cooling effect is mild.

It is therefore possible to make small a difference between the operating temperature of the thermoelectric generating device 20 nearest to the heat generation source and the operating temperature of the thermoelectric generating device 20 nearest to the heat absorber.

Further, in the twelfth embodiment, each of the inner thermal conducting members 21 other than the outermost thermal conducting members 21 becomes gradually thicker from the end connected to the first thermal coupling member 22 or the second thermal coupling member 23 toward the distal end. It is therefore possible to make gentle a temperature gradient near at the distal end of the inner thermal conducting member 21. It is therefore possible to suppress a temperature difference in the in-plane direction from being made small. An average thickness of each thermal conducting member 21 connected to the first thermal coupling member 22 becomes thicker with distance from the heat generation source. Similarly, an average thickness of each thermal conducting member 21 connected to the second thermal coupling member 23 becomes thicker with distance from the heat absorber.

In the twelfth embodiment, although a thickness of the inner thermal conducting member 21 is changed, a thickness of only the first thermal coupling member 22 and the second thermal coupling member 23 may be changed and a thickness of the inner thermal conducting member 21 may be made uniform. Also in the twelfth embodiment, although the thicknesses (cross sectional areas of thermal paths) of the first thermal coupling member 22 and the second thermal coupling member 23 are changed gradually and continuously, the thicknesses may be changed stepwise. If the thicknesses are changed stepwise, the number of steps may be equal to or larger than two.

### Thirteenth Embodiment

FIG. 19 is a cross sectional view of a thermoelectric generator of the thirteenth embodiment. Description will be made by paying attention to the different points from the thermoelectric generator of the second embodiment illustrated in FIG. 2. Duplicative description of the same structures as those of the second embodiment is omitted.

Six thermal conducting members 21A to 21F are disposed from a heat generation source 70 toward a heat absorber 71 such as a heat sink. A thermoelectric generating device 20 is sandwiched between adjacent thermal conducting members. First, third and fifth thermal conducting members 21A, 21C and 21E are connected to the first thermal coupling member 22, and second, fourth and sixth thermal conducting members 21B, 21D and 21F are connected to the second thermal coupling member 23.

In the thirteenth embodiment, the first thermal coupling member 22 includes a relatively thin portion 22A and a relatively thick portion 22B, which are continuous to each other. The thin portion 22A is connected to the first thermal conducting member 21A and the third thermal conducting member 21C, and the thick portion 22B is connected to the third thermal conducting member 21C and the fifth thermal conducting member 21E.

The second thermal coupling member 23 also includes a relatively thin portion 23A and a relatively thick portion 23B, which are continuous to each other. The thin portion 23A is connected to the sixth thermal conducting member 21F and the fourth thermal conducting member 21D, and the thick portion 23B is connected to the fourth thermal conducting member 21D and the second thermal conducting member 21B.

The first thermal coupling member 22 and the second thermal coupling member 23 of the thirteenth embodiment corresponds to the first thermal coupling member 22 and the second thermal coupling member 23 of the twelfth embodiment illustrated in FIG. 18 having the thicknesses changed stepwise.

The fifth thermal conducting member 21E is thicker than the other first and third thermal conducting members 21A and 21C connected to the first thermal coupling member 22. The second thermal conducting member 21B is thicker than the other fourth and sixth thermal conducting members 21D and 21F connected to the second thermal coupling member 23.

For example, the thicknesses of the thin portion 22A of the first thermal coupling member 22, the thin portion 23A of the second thermal coupling member 23, the first, third, fourth and sixth thermal conducting members 21A, 21C, 21D and 21F are 100 μm. The thicknesses of the thick portion 22B of the first thermal coupling member 22, the thick portion 23B of the second thermal coupling member 23, the second and fifth thermal conducting members 21B and 21E are 180 μm.

Each of the first thermal coupling member 22 and the second thermal coupling member 23 is formed by press bonding or welding a thin steel plate for the thin portion and a thick steel plate for the thick portion.

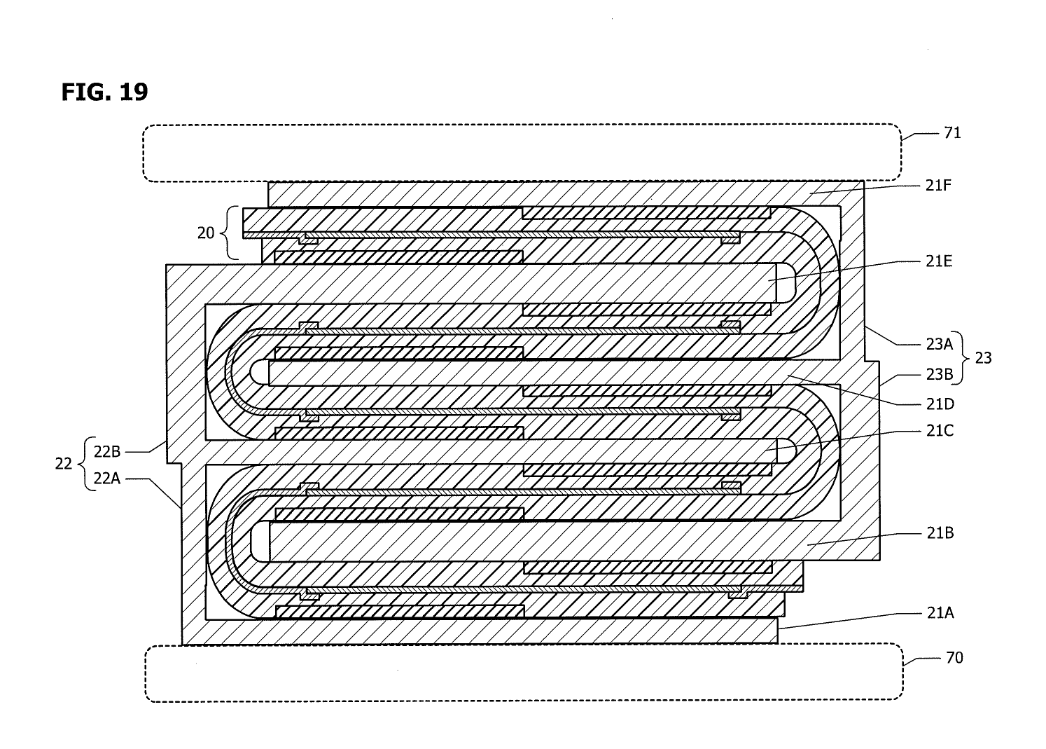

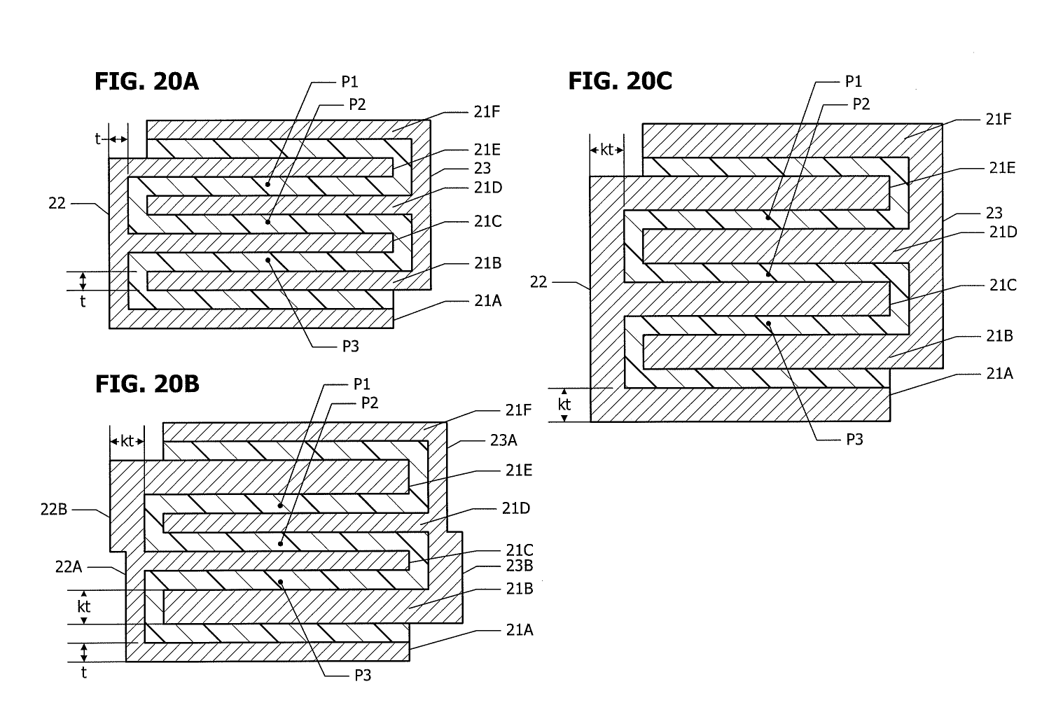

FIG. 20A to FIG. 20C are cross sectional views of samples used for temperature distribution simulations. In the samples illustrated in FIG. 20A and FIG. 20C, the thicknesses of the first thermal coupling member 22, the second thermal coupling member 23, and first to sixth thermal conducting members 21A to 21F are equal. However, each portion of the sample illustrated in FIG. 20C is thicker than a corresponding portion of the sample illustrated in FIG. 20A. The sample illustrated in FIG. 20B corresponds to the structure of the thermoelectric generator of the thirteenth embodiment illustrated in FIG. 19.

The thicknesses of the thermal conducting members 21A to 21F, the first thermal coupling member 22 and the second thermal coupling member 23 of the sample illustrated in FIG. 20A are represented by “t”. The thicknesses of the first, third, fourth and sixth thermal conducting members 21A, 21C, 21D and 21F, the thin portion 22A of the first thermal coupling member 22 and the thin portion 23A of the second coupling member 23 are set to “t”. The thicknesses of the second and fifth thermal conducting members 21B and 21E, the thick portion 22B of the first thermal coupling member 22 and the thick portion 23B of the second thermal coupling member 23 are set to “kt” thicker than “t”. “k” is a thickness magnification constant. In the sample illustrated in FIG. 20C, the thicknesses of the thermal conducting members 21A to 21F, the first thermal coupling member 22 and the second thermal coupling member 23 are set to “kt”.

For all samples, temperatures were calculated through simulations at the center P1 of the thermoelectric generating device between the fourth thermal conducting member 21D and the fifth thermal conducting member 21E, at the center P2 of the thermoelectric generating device between the third thermal conducting member 21C and the fourth thermal conducting member 21D, and at the center P3 of the thermoelectric generating device between the second thermal conducting member 21B and the third thermal conducting member 21C. The simulations were conducted under the conditions that aluminum is disposed in a space occupied by the thermal conducting members 21A to 21F, the first thermal coupling member 22 and the second thermal coupling member 23, and polyimide is disposed in a space occupied by the thermoelectric generating device among the thermal conducting members 21A to 21F. For the temperature boundary conditions, an outer surface temperature of the first thermal conducting member 21A was set to 100° C., an outer surface temperature of the sixth thermal conducting member 21F was set to 0° C.

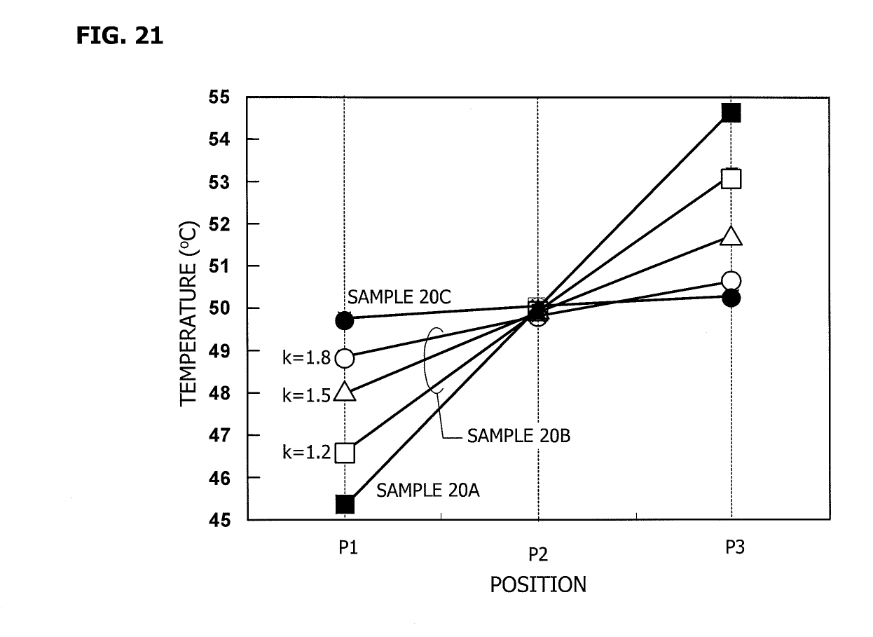

Simulation results are illustrated in FIG. 21. The abscissa of FIG. 21 corresponds to positions P1, P2 and P3 in the thermoelectric generators. The ordinate represents a temperature in the unit of “° C.”. Solid square symbols indicate temperatures of the sample illustrated in FIG. 20A, and solid circle symbols indicate temperatures of the sample illustrated in FIG. 20C. Empty square symbols, empty triangle symbols and empty circle symbols indicate temperatures of the sample illustrated in FIG. 20B at k=1.2, k=1.5 and k=1.8, respectively.

It is seen that the sample illustrated in FIG. 20B has a smaller variation in temperatures than the sample illustrated in FIG. 20A. The sample illustrated in FIG. 20C is most excellent if a temperature variation viewpoint only is paid attention. However, since the sample illustrated in FIG. 20C has all thick thermal conducting members 21A to 21F, this sample is inferior in flexibility. By adopting the structure illustrated in FIG. 20B, it becomes possible to suppress a temperature variation without reducing flexibility. The structure illustrated in FIG. 20B is superior to the structure illustrated in FIG. 20C in material cost.

In the thirteenth embodiment, paying attention to the thermal conducting members connected to the first thermal coupling member 22, the first thermal conducting member 21A and the third thermal conducting member 21C are set to have the same thickness, and only the fifth thermal conducting member 21E is made thicker. However, the third thermal conducting member 21C may be set to have a thickness intermediate between a thickness of the first thermal conducting member 21A and a thickness of the fifth thermal conducting member 21E.

More generally, paying attention to the thermal conducting members 21A, 21C and 21E connected to the first thermal coupling member 22, the thermal conducting member disposed at a first end in the stacked direction of thermoelectric generating devices is thinnest, and the thermal conducting member becomes thicker with distance from the thermal conducting member at the first end. Paying attention to the thermal conducting members 21B, 21D and 21F connected to the second thermal coupling member 23, the thermal conducting member disposed at a second end opposite to the first end in the stacked direction is thinnest, and the thermal conducting member becomes thicker with distance from the thermal conducting member at the second end.

### Fourteenth Embodiment

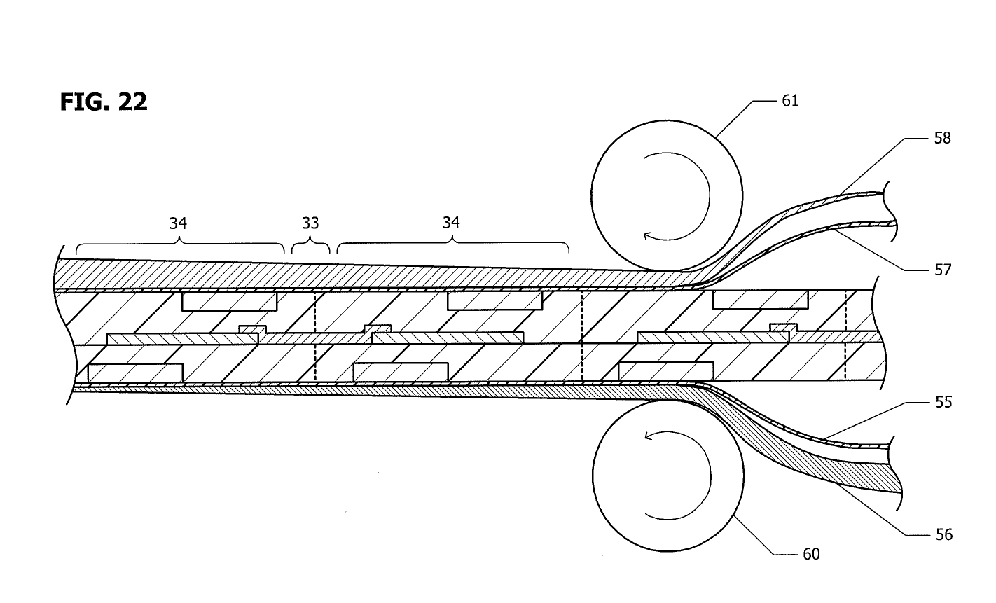

FIG. 22 is a cross sectional view of a thermoelectric generator of the fourteenth embodiment at an intermediate stage of manufacture. Description will be made by paying attention to the different points from the thermoelectric generator of the eighth embodiment illustrated in FIG. 11. Duplicative description of the same structures as those of the eighth embodiment is omitted.

In the eighth embodiment, the thicknesses of the thermal conducting films 56 and 58 are uniform. The thicknesses of the thermal conducting films 56 and 58 of the fourteenth embodiment are monotonously changes in the direction (folding direction) in which the thermoelectric generating parts 34 and the folded parts 33 are arranged. One thermal conducting film 56 becomes gradually thicker from one end (left end in FIG. 22) toward the other end (right end in FIG. 22). Conversely, the other thermal conducting film 58 becomes gradually thinner from the one end (left end in FIG. 22) to the other end (right end in FIG. 22). For example, copper, aluminum or the like is used for the thermal conducting films 56 and 58. The structure of gradually changing a thickness may be formed, e.g., by changing and adjusting a rolling pressure.

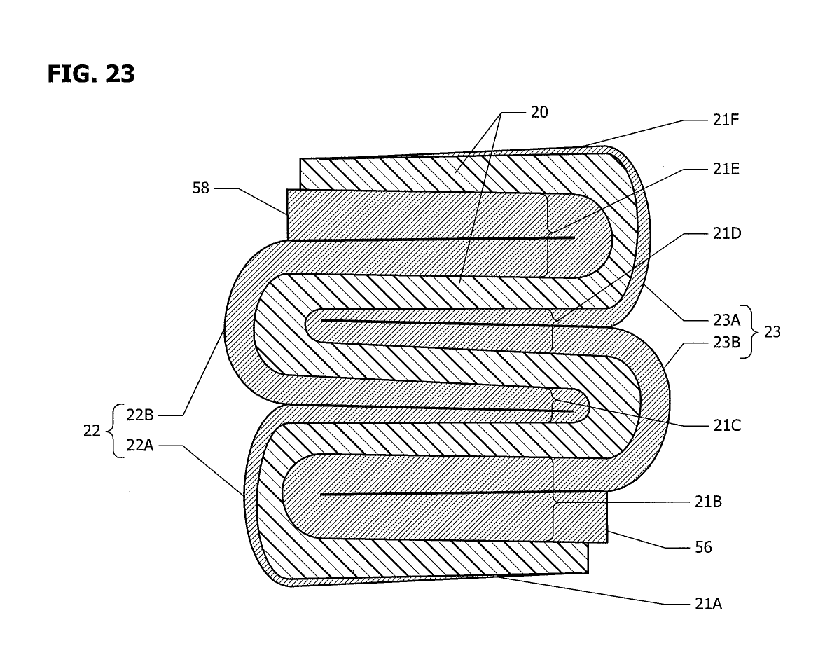

FIG. 23 is a cross sectional view of a thermoelectric generator of the fourteenth embodiment. Thermoelectric generating devices 20 is folded up in such a manner that thin end portions of thermal conducting films 56 and 58 are disposed at the outermost sides. In FIG. 23, a trace of the detail structures of the thermoelectric generating devices 20 are omitted. Trace of two-sided adhesive sheets 55 and 57 (FIG. 22) are also omitted.

Of the thermal conducting film 58, a portion in tight contact with the outer surface of the outermost thermoelectric generating device 20 serves as the first thermal conducting member 21A. Of the thermal conducting film 58, portions sandwiched between the thermoelectric generating devices 20 serve as the third and fifth thermal conducting members 21C and 21E. Of the other thermal conducting film 58, a portion in tight contact with the outer surface of the outermost thermoelectric generating device 20 serves as the sixth thermal conducting member 21F. Of the thermal conducting film 56, portions sandwiched between the thermoelectric generating devices 20 serve as the second and fourth thermal conducting members 21B and 21D.

Of the thermal conducting films 58 and 56, portions in tight contact with the folded portion 33 (FIG. 22) serve as the first thermal coupling member 22 and the second thermal coupling member 23. Since a thickness of the thermal conducting film 58 changes monotonously, a portion 22A interconnecting the first thermal conducting member 21A and the third thermal conducting member 21C gradually thickens from a connection point with the first thermal conducting member 21A toward a connection point with the third thermal conducting member 21C. Similarly, a portion 22B interconnecting the third thermal conducting member 21C and the fifth thermal conducting member 21E gradually thickens from a connection point with the third thermal conducting member 21C toward a connection point with the fifth thermal conducting member 21E.

The first thermal coupling member 22 and the second thermal coupling member 23 of the thermoelectric generator of the fourteenth embodiment have a thickness distribution tendency similar to that of the first thermal coupling member 22 and the second thermal coupling member 23 of the twelfth embodiment illustrated in FIG. 18.

Paying attention to the first, third and fifth thermal conducting members 21A, 21C and 21E connected to the first thermal coupling member 22, the first thermal conducting member 21A being in contact with the heat generation source is thinnest, and the thermal conducting member becomes thicker with distance from first thermal conducting member 21A. Similarly, paying attention to the second, fourth and sixth thermal conducting members 21B, 21D and 21F connected to the second thermal coupling member 23, the sixth thermal conducting member 21F being in contact with the heat absorber is thinnest, and the thermal conducting member becomes thicker with distance from the sixth thermal conducting member 21F.

### Fifteenth Embodiment

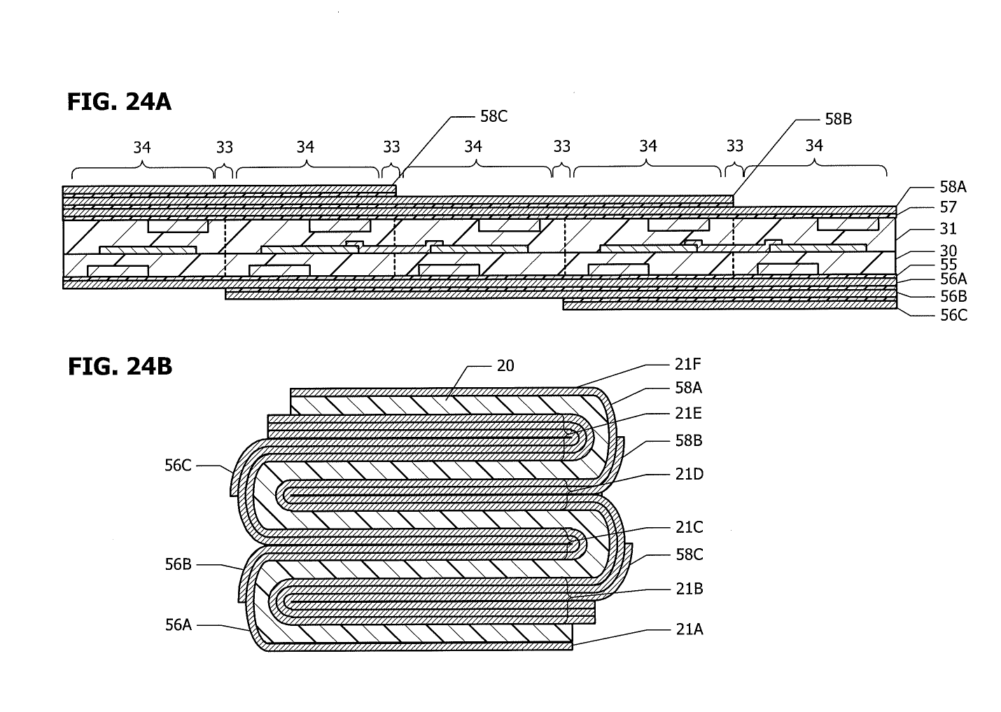

FIG. 24A is a cross sectional view of a thermoelectric generator of the fifteenth embodiment at an intermediate stage of manufacture. Description will be made by paying attention to the different points from the thermoelectric generator of the eighth embodiment illustrated in FIG. 11. Duplicative description of the same structures is omitted. In the eighth embodiment, one thermal conducting film 56 is bonded to the surface of the first flexible film 30, and one thermal conducting film 58 is bonded to the surface of the second flexible film 31.

In the fifteenth embodiment, three thermal conducting films 56A, 56B and 56C are bonded to the surface of a first flexible film 30 with two-sided adhesive sheets 55. The first thermal conducting film 56A is bonded to an area from the thermal electric generating part 34 at one end (left end in FIG. 24A) to the thermal electric generating part 34 at the other end (right end in FIG. 24A). The second thermal conducting film 56B is bonded to an area from the second electric generating part 34 to the fifth electric generating part 34 as counted from the left in FIG. 24A. The third thermal conducting film 56C is bonded to an area from the fourth electric generating part 34 to the fifth electric generating part 34 as counted from the left in FIG. 24A. Namely, one, two, two, three and three thermal conducting films are bonded to the first to fifth thermoelectric generating parts 34 of the first flexible film 30, respectively.

Three heat conductive films 58A, 58B and 58C are also bonded to the second flexible film 31 with a two-sided adhesive sheets 57. The order of the number of thermal conducting films bonded to each thermoelectric generating part 34 of the first flexible film 30 and the order of the number of thermal conducting films bonded to each thermoelectric generating part 34 of the second flexible film 31 have a mutually reversed relation.

More generally, the numbers of thermal conducting films bonded to the first flexible film 30 increase from one end (left end in FIG. 24A) in the folding direction toward the other end (right end), whereas the numbers of thermal conducting films bonded to the second flexible film 31 decreases from one end (left end in FIG. 24A) in the folding direction toward the other end (right end).

FIG. 24B is a schematic cross sectional view of the thermoelectric generator of the fifteenth embodiment. In FIG. 24B, trace of the detailed structure of the thermoelectric generating devices 20 and the two-sided adhesive sheets 55 and 57 are omitted. The first flexible film 30 and the second flexible film 31 are folded up in such a manner that the surface with a single thermal conducting film 56A being bonded to and the surface with a single thermal conducting film 58A being bonded to are disposed at the outermost side.

The first thermal conducting member 21A is constituted of one thermal conducting film 56A. The second thermal conducting member 21B is constituted of three thermal conducting films 58A, 58B and 58C, and has a lamination structure of six thermal conducting films folded together. Similarly, each of the third and fourth thermal conducting members 21C and 21D has the lamination structure of four thermal conducting films. The fifth thermal conducting member 21E has a lamination structure of six thermal conducting films. The sixth thermal conducting member 21F is constituted of one thermal conducting film 58A.

Paying attention to the first, third and fifth thermal conducting members 21A, 21C and 21E, the thermal conducting members become therefore thicker with distance from the heat generation source being in contact with the first thermal conducting member 21A. Similarly, paying attention to the second, fourth, and sixth thermal conducting members 21B, 21D and 21F, the thermal conducting members become therefore thicker with distance from the heat absorber being in contact with the sixth thermal conducting member 21F.

In the fifteenth embodiment, it is not necessary to prepare a thermal conducting film used in the fourteenth embodiment whose thickness gradually changes, but it is sufficient to prepare a thermal conducting film having a uniform thickness.

### Sixteenth Embodiment

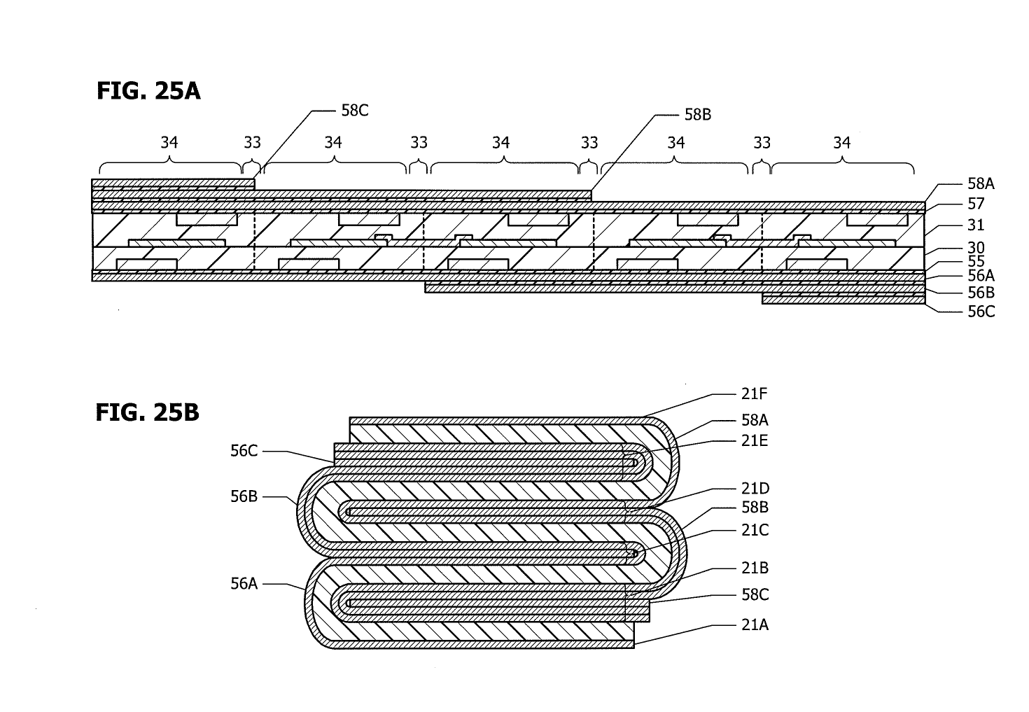

FIG. 25A is a cross sectional view of a thermoelectric generator of the sixteenth embodiment at an intermediate stage of manufacture. Description will be made by paying attention to the different points from the thermoelectric generator of the fifteenth embodiment illustrated in FIG. 24A. Duplicative description of the same structures is omitted. In the sixteenth embodiment, the numbers of thermal conducting films bonded to the first flexible film 30 and second flexible film 31 in the second thermoelectric generating part 34 as counted from the left in FIG. 25A are smaller by one film than those of the fifteenth embodiment. Further, the numbers of thermal conducting films bonded to the first flexible film 30 and the second flexible film 31 in the fourth thermoelectric generating parts 34 as counted from the left in FIG. 25A are smaller by one film than those of the fifteenth embodiment.

FIG. 25B is a cross sectional view of a thermoelectric generator of the sixteenth embodiment. Description will be made by paying attention to the different points from the thermoelectric generator of the fifteenth embodiment illustrated in FIG. 24B. Duplicated description of the same structures is omitted.

In the sixteenth embodiment, each of the second thermal conducting member 21B and the fifth thermal conducting member 21E is constituted of five thermal conducting films. Further, each of the third thermal conducting member 21C and the fourth thermal conducting member 21D is constituted of three thermal conducting films.

Also in the sixteenth embodiment, paying attention to the first, third and fifth thermal conducting members 21A, 21C and 21E, the thermal conducting members become therefore thicker with distance from the heat generation source being in contact with the first thermal conducting member 21A. Similarly, paying attention to the second, fourth, and sixth thermal conducting members 21B, 21D and 21F, the thermal conducting members become therefore thicker with distance from the heat absorber.

As in the case of the fifteenth embodiment, it is not necessary to prepare a thermal conducting film used in the fourteenth embodiment whose thickness gradually changes, but it is sufficient to prepare a thermal conducting film having a uniform thickness.

### Seventeenth Embodiment

Next, a thermoelectric generator of the seventeenth embodiment will be described, by paying attention to the different points from the thermoelectric generator of the fourth embodiment illustrated in FIG. 6. Duplicative description of the same structures as those of the fourth embodiment is omitted.

The manufacture processes for the thermoelectric generator of the fourth embodiment illustrated in FIG. 3Aa, FIG. 3Ab to FIG. 3Ea, FIG. 3Eb are common to the manufacture processes for the thermoelectric generator of the seventeenth embodiment. Description will be made on the processes after the state illustrated in FIG. 3Ea and FIG. 3Eb.

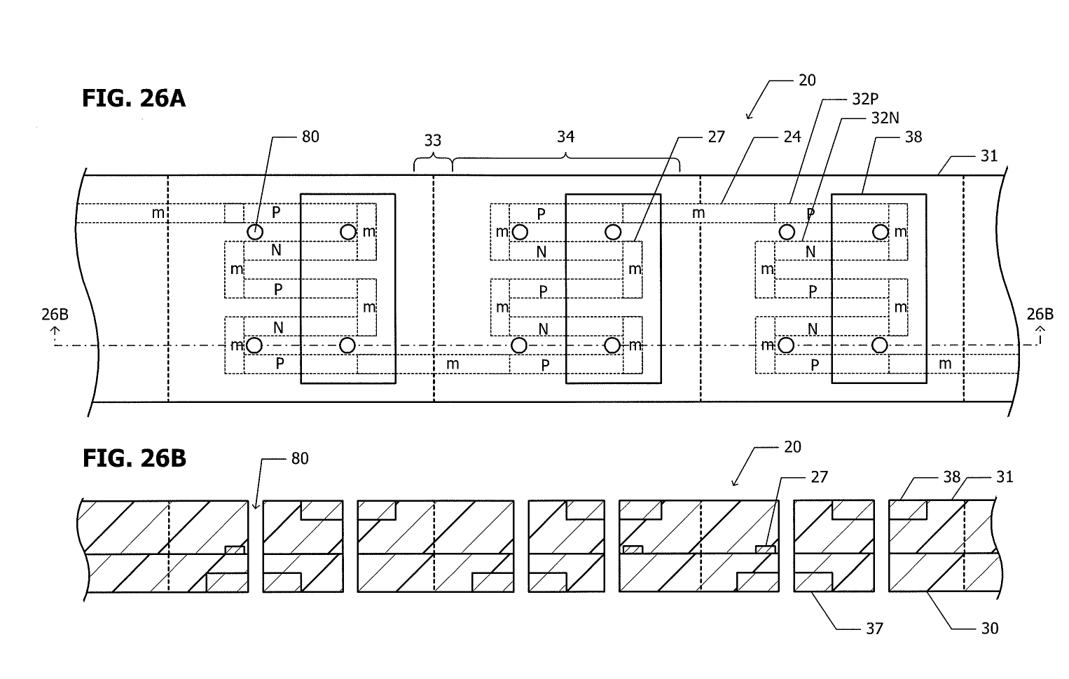

FIG. 26A is a planar view of a thermoelectric generating device 20 before being folded up. FIG. 26B is a cross sectional view taken along one-dot chain line 26B-26B in FIG. 26A. A plurality of through holes 80 are formed through the first flexible film 30, the second flexible film 31, the first good thermal conductor 37 and the second thermal conductor 38. The through holes 80 are disposed within the thermoelectric generating parts 34 at positions overlapping neither the interlayer wirings 24, the intra-layer wirings 27, the p-type thermoelectric conversion patterns 32P nor the n-type thermoelectric conversion patterns 32N. When the thermoelectric generating device 20 is folded up, the through holes 80 overlap in the stacked direction.

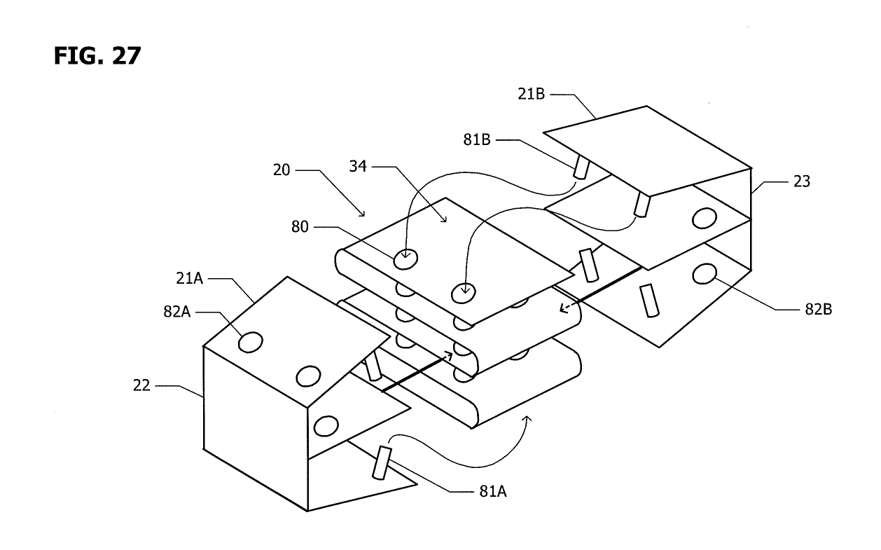

FIG. 27 is a perspective view of the folded thermoelectric generating device 20 and the thermal conducting members 21. As in the case of the fourth embodiment, three first thermal conducting members 21A are connected to the first thermal coupling member 22, and three second thermal conducting members 21B are connected to the second thermal coupling member 23.

Of three first thermal conducting members 21A, first thermal conducting columns (first thermal conducting structure) 81A are mounted on the inner surface of the outermost first thermal conducting member 21A. Similarly, of three second thermal conducting members 21B, second thermal conducting columns (second thermal conducting structure) 81B are mounted on the inner surface of the outermost second thermal conducting member 21B. As in the case of the thermal conducting member 21, material having a high thermal conductivity such as copper, aluminum and the like is used for the first and second thermal conducting columns 81A and 81B.

First through holes 82A and second through holes 82B are formed through the first thermal conducting members 21A and the second thermal conducting members 21B, respectively. When the first thermal conducting member 21A is inserted between thermoelectric generating parts 34, the first through holes 82A overlap with the through holes 80 formed in the thermoelectric generating parts 34. Similarly, when the second thermal conducting member 21B is inserted between thermoelectric generating parts 34, the second through holes 82B overlap with the through holes 80. First through holes 82A and the second through holes 82B do not overlap with each other.

In assembling the thermoelectric generator, the second thermal conducting column 81B passes through the through hole 80 and the first through hole 82A and reaches the middle second thermal conducting member 21B. The first thermal conducting column 81A passes through the through hole 80 and the second through hole 82B and reaches the middle first thermal conducting member 21A.

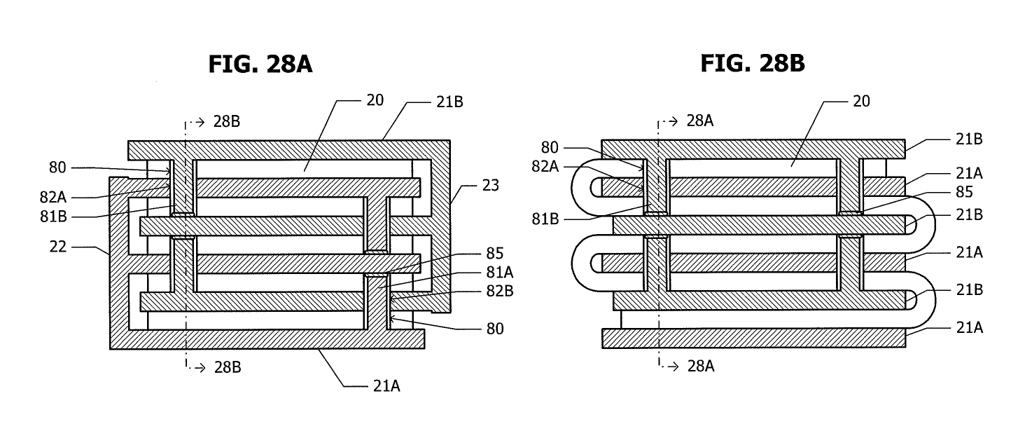

FIG. 28A and FIG. 28B are cross sectional views of the thermoelectric generator after assembly. FIG. 28B corresponds to a cross sectional view taken along one-dot chain line 28B-28B in FIG. 28A, and FIG. 28A corresponds to a cross sectional view taken along one-dot chain line 28A-28A in FIG. 28B.

The first thermal conducting member 81A sequentially passes through the through hole 80, the second through hole 82B and the through hole 80 and reaches the middle first thermal conducting member 21A. The first thermal conducting column 81A is fixed to, and thermally coupled to, the middle first thermal conducting member 21A by, e.g., solder 85. Similarly, the second thermal conducting member 81B sequentially passes through the through hole 80, the second through hole 82A and the through hole 80 and reaches the middle second thermal conducting member 21B. The second thermal conducting column 81B is fixed to, and thermally coupled to, the middle second thermal conducting member 21B by, e.g., solder 85.

The solder 85 is provided at the top ends of the first thermal conducting column 21A and the second thermal conducting column 21B in advance before assembly. After the assembly, the first thermal conducting member 21A and the second thermal conducting member 21B are heated to a temperature equal to or higher than the solder melting point, and thereafter cooled to fix the first thermal conducting column 81A to the first thermal conducting member 21A via the solder 85, and to fix the second thermal conducting column 81B to the second thermal conducting member 21B via the solder 85.

The first thermal conducting column 81A is not in contact with the second thermal conducting member 21B at the position passing through the second through hole 82B to be thermally separated from the second thermal conducting member 21B. Similarly, the second thermal conducting column 81B is also thermally separated from the first thermal conducting member 21A. “Being thermally separated” does not mean a perfect heat shielding condition, but means that the thermal conducting column is not coupled via a member having a higher thermal conductivity than that of the first flexible film 30 and the second flexible film 31.

A distance from the first thermal coupling member 22 to the first thermal conducting column 81A is longer than a distance from the first thermal coupling member 22 to the second thermal conducting column 81B. Similarly, a distance from the second thermal coupling member 23 to the second thermal conducting column 81B is longer than a distance from the second thermal coupling member 23 to the first thermal conducting column 81A.

Consider the case in which the outermost first thermal conducting member 21A is in contact with a heat generation source, and the outermost second thermal conducting member 21B is in contact with a heat absorber. Heat is transferred from the outermost first thermal conducting member 21A to the inner first thermal conducting member 21A via the first thermal coupling member 22 and the first thermal conducting column 81A. Heat is transferred to the outermost second thermal conducting member 21B from the inner second thermal conducting member 21B via the second thermal coupling member 23 and the second thermal conducting column 81B.

As compared to the case in which the first and second thermal conducting columns 81A and 81B are not provided, it becomes possible to efficiently heat the inner first thermal conducting member 21A and efficiently cool the inner second thermal conducting member 21B. It is therefore possible to improve an electric power generation efficiency.

Heat is more difficult to be transferred to the region of the first thermal conducting member 21A with distance from the first thermal coupling member 22. It is therefore preferable to dispose the first thermal conducting column 81A in the region where heat is difficult to be transferred. For example, the first thermal conducting column 81A is preferably disposed at a position remoter than the middle point of the first thermal conducting member 21A as viewed from the first thermal coupling member 22. The preferable position where the second thermal conducting member 21B is disposed is similar to the preferable position of the first thermal conducting member 21A.

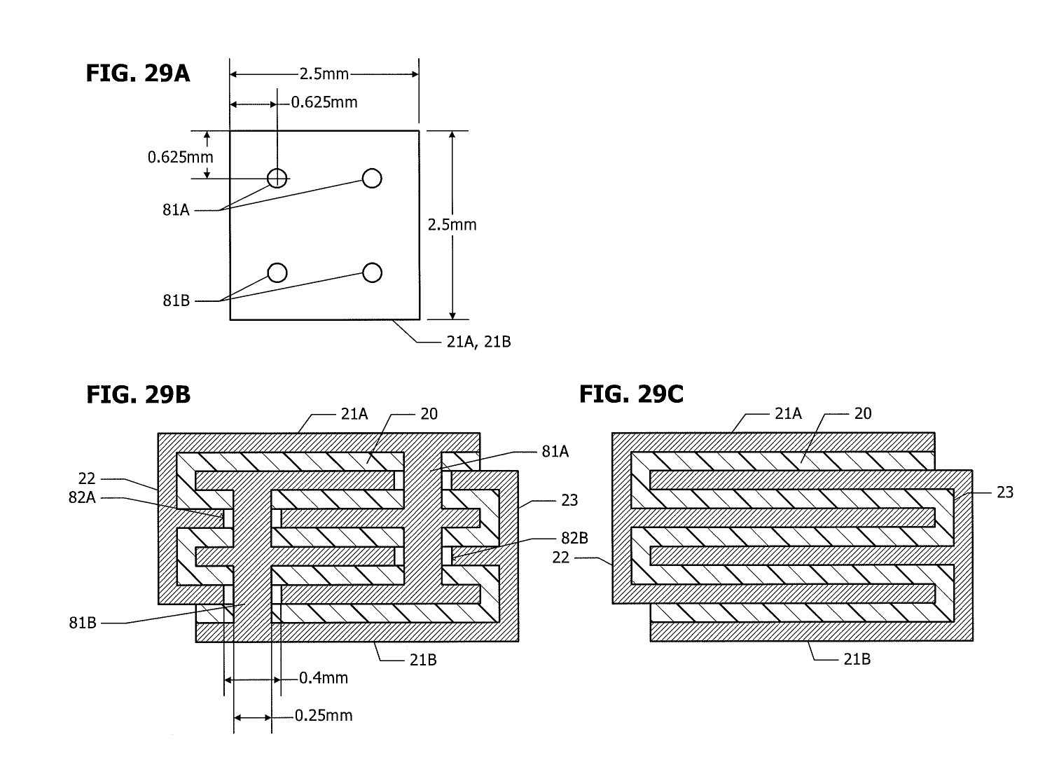

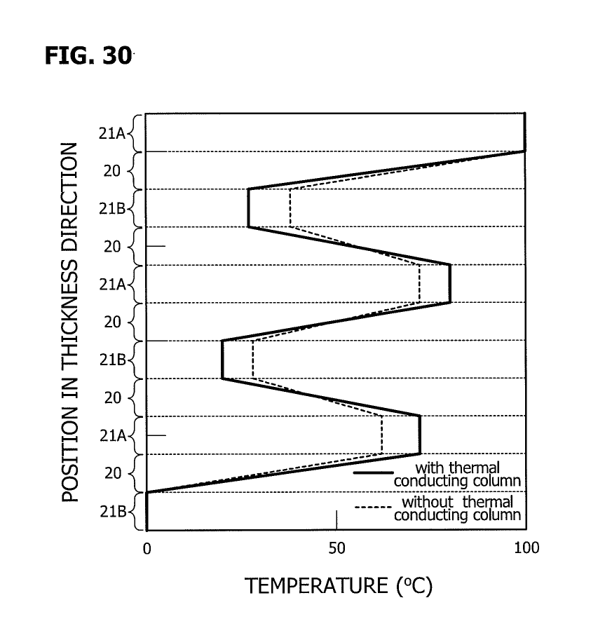

Next, with reference to FIG. 29A to FIG. 30, description will be made on the results of simulation executed in order to confirm the effects of the first and second thermal conducting columns 81A and 81B.

FIG. 29A is a plan view of a sample to be simulated. A planar shape of the first and second thermal conducting members 21A and 21B is a square having a side length of 2.5 mm. The first thermal conducting columns 81A are disposed on diagonal lines at positions slightly inner than adjacent two apexes, and the second thermal conducting columns 81B are disposed on diagonal lines at positions slightly inner than adjacent other two apexes. A cross section of each of the first and second thermal conducting columns 81A and 81B is a circle having a diameter of 0.25 mm. A distance from each side to the center of each of the first and second thermal conducting columns 81A and 81B is set to 0.625 mm.

FIG. 29B is a cross sectional view of a sample to be simulated. A planar shape of each of the first and second through holes 82A and 82B is a circle having a diameter of 0.4 mm. The thermoelectric generating device 20A is represented by a sheet of 0.1 mm thick made mainly of polyimide, and the first and second thermal conducting members 21A and 21B and the first and second thermal coupling members 22 and 23 are represented by sheets of 0.1 mm thick made mainly of aluminum. The material for the first and second thermal conducting columns 81A and 81B is the same as the first and second thermal conducting members 21A and 21B.

FIG. 29C is a cross sectional view of a sample according to a comparative example not providing the first and second thermal conducting columns. In the comparative example, through holes are not formed through the thermoelectric generating device 20 and the first and second thermal conducting members 21A and 21B.

An outer surface temperature of the outermost first thermal conducting member 21A was set to 100° C., and an outer surface temperature of the outermost second thermal conducting member 21B was set to 0° C. Under this condition, temperatures at positions in the thermoelectric generator were calculated by three-dimensional model simulation.

FIG. 30 illustrates simulation results of a temperature distribution in a thickness direction at positions corresponding to the centers of the first thermal conducting members 21A. The abscissa represents a temperature in the unit of “° C.”, and the ordinate represents a position in the thickness direction. A Bold solid line in FIG. 30 indicates the simulation result of the sample corresponding to the seventeenth embodiment illustrated in FIG. 29A and FIG. 29B, and a thin broken line indicates the simulation result of the comparative example illustrated in FIG. 29C. It is seen that a temperature difference between both sides of each layer of the thermoelectric generating device 20 of the sample corresponding to the seventeenth embodiment is larger than that of the sample corresponding to the comparative example.

It is therefore possible to generate a larger temperature difference by disposing the first and second thermal conducting columns 81A and 81B. It becomes therefore possible to improve an electric power generation efficiency. Generally, an electric power generation is proportional to a square of a temperature difference. An electric power generated by the sample corresponding to the seventeenth embodiment is about 1.5 times the electric power generated by the sample according to the comparative example illustrated in FIG. 29C.

In the seventeenth embodiment, the first and second thermal conducting columns 81A and 81B are provided in the thermoelectric generator of the fourth embodiment. The first and second thermal conducting columns 81A and 81B may be provided also in the thermoelectric generator of the second embodiment illustrated in FIG. 2, the third embodiment illustrated in FIG. 5, the fifth embodiment illustrated in FIG. 7, the sixth embodiment illustrated in FIG. 9, the ninth embodiment illustrated in FIG. 13, the twelfth embodiment illustrated in FIG. 18, or the thirteenth embodiment illustrated in FIG. 19.

### Eighteenth Embodiment

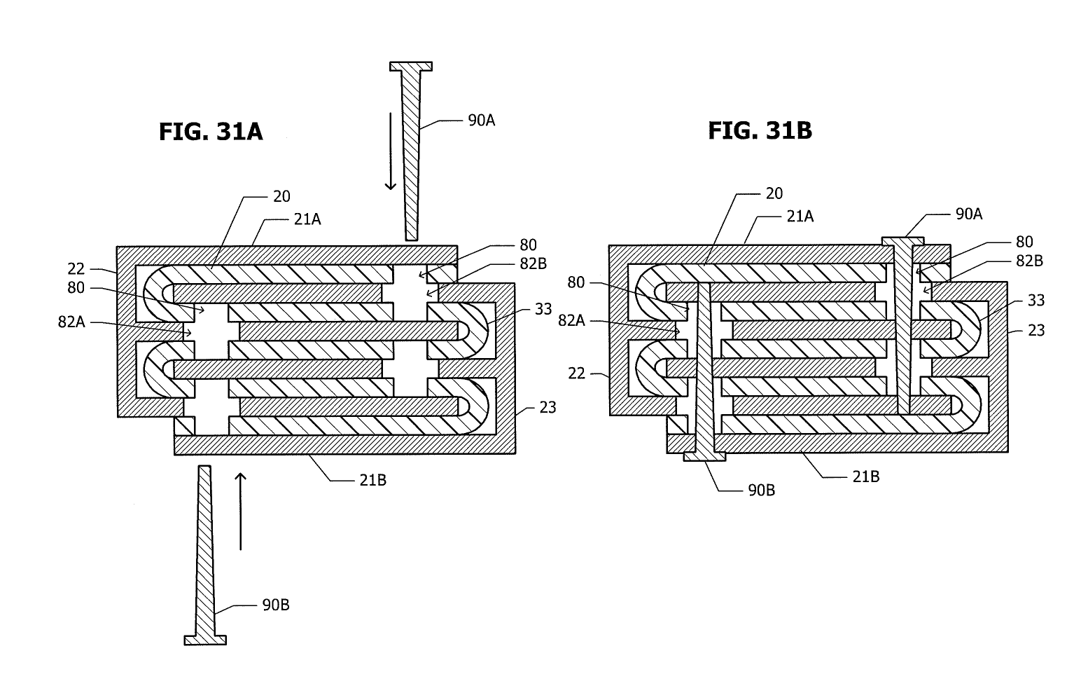

FIG. 31A is a cross sectional view of a thermoelectric generator of the eighteenth embodiment at an intermediate stage of manufacture. Description will be made by paying attention to the different points from the thermoelectric generator of the seventeenth embodiment illustrated in FIG. 28A and FIG. 28B. Duplicative description of the same structures as those of the seventeenth embodiment is omitted.

As in the case of the thermoelectric generator of the seventeenth embodiment, the through holes 80 are formed through a thermoelectric generating device 20, the first through holes 82A are formed through the first thermal conducting members 21A, and the second through holes 82B are formed through the second thermal conducting members 21B. The first and second thermal conducting columns 81A and 81B (FIG. 28A and FIG. 28B) are not provided. In the eighteenth embodiment, a first thermal conducting pin 90A and a second thermal conducting pin 90B are prepared in place of the first and second thermal conducting columns 81A and 81B. The first and second thermal conducting pins 90A and 90B are made of material having a high thermal conductivity such as copper, aluminum and the like.

As illustrated in FIG. 28A, in the seventeenth embodiment, the first thermal coupling member 22 and the second thermal coupling member 23 are disposed along the side walls on which the folded portions 33 do not appear. In the eighteenth embodiment, the first thermal coupling member 22 and the second thermal coupling member 23 are disposed along the side walls on which the folded portions 33 appear. They may be disposed along the side walls on which the folded portions 33 do not appear as in the case of the seventeenth embodiment.

As illustrated in FIG. 31B, the first thermal conducting pin 90A pierces through the outermost first thermal conducting member 21A and is inserted into the through holes 80 and the second through hole 82B. The first thermal conducting pin 90A further pierces through the middle first thermal conducting member 21A and is inserted into the through holes 80 and the second through hole 82B, and reaches the opposite first thermal conducting member 21A. Similarly, the second thermal conducting pin 90B pierces through the outermost second thermal conducting member 21B and the middle second thermal conducting member 21B, passes through the through holes 80 and the first through holes 82A, and reaches the opposite second thermal conducting member 21B.

The first thermal conducting pin 90A is in contact with the first thermal conducting member 21A so that both are thermally coupled. By covering the side wall of the first thermal conducting pin 90A with solder in advance, and after the first thermal conducting pin 90A is inserted, the solder may be melted and solidified to improve thermal transfer efficiency between the first thermal conducting pin 90A and the first thermal conducting member 21A. Similarly, the side wall of the second thermal conducting pin 90B may be covered with solder in advance.

The first thermal conducting pin 90A is not in contact with the second thermal conducting member 21B, and the second thermal conducting pin 90B is not in contact with the first thermal conducting member 21A.

The first thermal conducting pin 90A and the second thermal conducting pin 90B have the same function as that of the first thermal conducting column (first thermal conducting structure) 81A and the second thermal conducting column (second thermal conducting structure) 81B of the seventeenth embodiment, respectively. Also in the eighteenth embodiment, an electric power generation efficiency is improved as in the case of the seventeenth embodiment.

In the eighteenth embodiment, the thermoelectric generating parts 34, the first thermal conducting member 21A and the second thermal conducting member 21B are assembled to be a stacked structure, and thereafter, the first and second thermal conducting pins 90A and 90B are inserted. As compared to the seventeenth embodiment, assembly is therefore easy.

### Nineteenth Embodiment

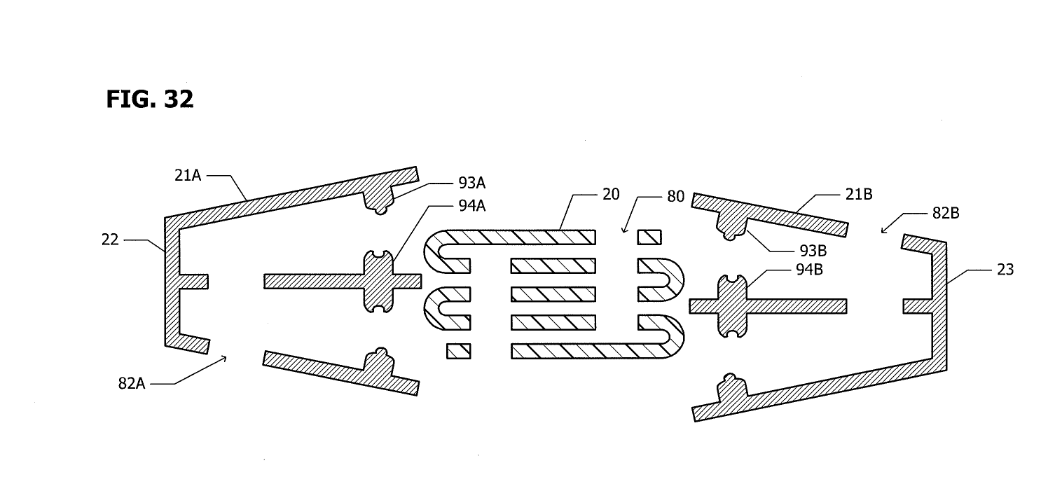

FIG. 32 is a cross sectional view of a thermoelectric generator of the nineteenth embodiment at an intermediate stage of manufacture. Description will be made by paying attention to the different points from the thermoelectric generator of the seventeenth embodiment illustrated in FIG. 28A and FIG. 28B. Duplicative description of the same structures as those of the seventeenth embodiment is omitted.

The through holes 80 which are the same as those of the seventeenth embodiment are formed through a thermoelectric generating device 20. First convex thermal conducting columns (jointing members) 93A are formed on the inner surface of the outermost first thermal conducting members 21A, and first concave thermal conducting columns (jointing members) 94A are formed on an inner surface of the middle first thermal conducting member 21A at positions corresponding to the first convex thermal columns 93A. The tip of the first convex thermal conducting columns 93A and the tip of the first concave thermal conducting columns 94A have geometric shapes which are jointed with each other. By jointing the tip of the first convex thermal conducting column 93A with the first concave thermal conducting column 94A, it is possible to fix the first convex thermal conducting column 93A to the first concave thermal conducting column 94A.

Similarly, the second convex thermal conducting columns (jointing members) 93B and the second concave thermal conducting columns (jointing members) 94B are provided in the second thermal conducting member 21B. As in the case of the seventeenth embodiment, the first through holes 82A and the second through holes 82B are formed through the first thermal conducting member 21A and the second thermal conducting member 21B.

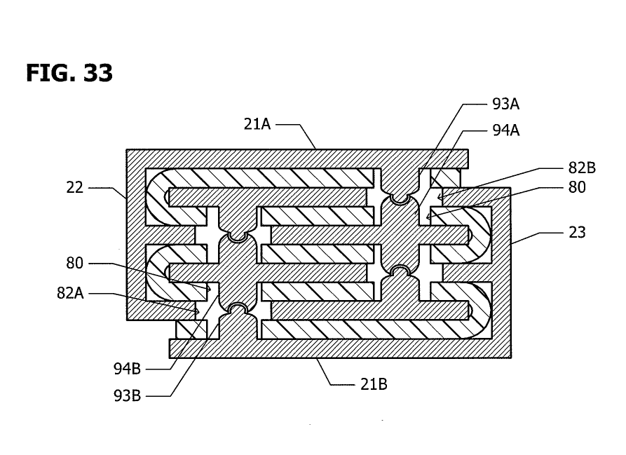

As illustrated in FIG. 33, in the assembled state, the first convex thermal conducting column 93A and the first concave thermal conducting column 94A are jointed with each other via the through holes 80 and the second through hole 82B. Similarly, the second convex thermal conducting column 93B and the second concave thermal conducting column 94B are jointed with each other via the through holes 80 and the first through hole 82A.

The first convex thermal conducting member 93A and the first concave thermal conducting member 94A which are jointed with each other have the same function as that of the first thermal conducting column (first thermal conducting structure) 81A of the seventeenth embodiment illustrated in FIG. 28A. Similarly, the second convex thermal conducting member 93B and the second concave thermal conducting member 94B which are jointed with each other have the same function as that of the second thermal conducting column (second thermal conducting structure) 81B of the seventeenth embodiment illustrated in FIG. 28A. An electric power generation efficiency is therefore improved as in the case of the seventeenth embodiment.

In the nineteenth embodiment, a heating process for melting solder is not necessary for assembly.

### Twentieth Embodiment

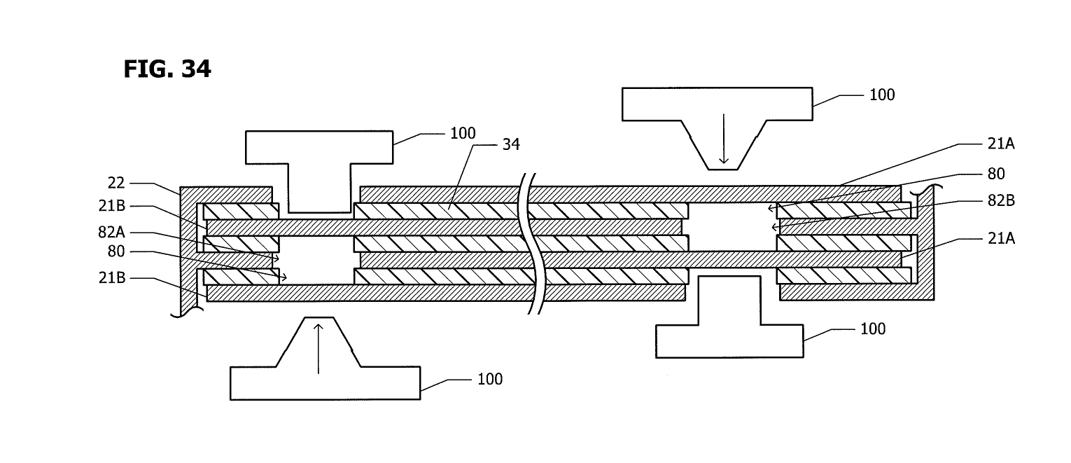

With reference to FIG. 34 to FIG. 37, description will be made on a manufacture method for a thermoelectric generator of the twentieth embodiment. Description will be made by paying attention to the different points from the thermoelectric generator of the seventeenth embodiment illustrated in FIG. 28A and FIG. 28B. Duplicative description of the same structures as those of the seventeenth embodiment is omitted.

As illustrated in FIG. 34, excepting the first thermal conducting member 21A and the second thermal conducting member 21B to be disposed at the outermost positions, two first thermal conducting members 21A and two second thermal conducting members 21B are alternately stacked with thermoelectric generating parts 34 being involved therebetween. The through holes 80 which are the same as those of the seventeenth embodiment are formed through the thermoelectric generating parts 34. The first through holes 82A and the second through holes 82B which are the same as those of the seventeenth embodiment are formed through the first thermal conducting member 21A and the second thermal conducting member 21B, respectively.

Portions of the two first thermal conducting members 21A face each other via the through hole 80 and the second through hole 82B. The facing portions are pressure bonded together using pressure bonding instruments 100. Similarly, portions of the two second thermal conducting members 21B facing each other via the through holes 80 and the first through hole 82A are pressure bonded together using pressure bonding instruments 100.

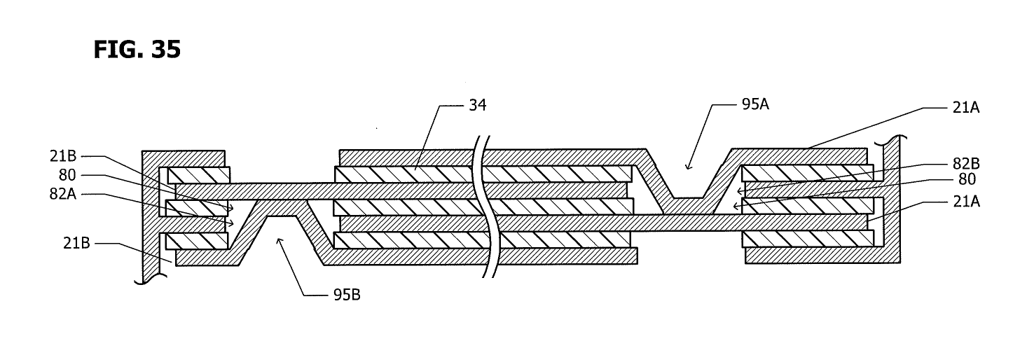

FIG. 35 is a partial cross sectional view of the thermoelectric generator after pressure bonding. At least one of two first thermal conducting members 21A is deformed to form a first recess 95A. A deformed portion of one of the first thermal conducting member 21A is bonded to the other of the first thermal conducting members 21A via the through holes 80 and the second through hole 82B. This deformed portion is not in contact with the second thermal conducting member 21B. It is therefore possible to retain good thermal coupling between the first thermal conducting members 21A, and it is possible for the first thermal conducting members 21A to be thermally separated from the second thermal conducting member 21B. Similarly, at least one of the two second thermal conducting members 21B is deformed and both are bonded with each other. A second recess 95B is formed on the surface of the second thermal conducting member 21B.

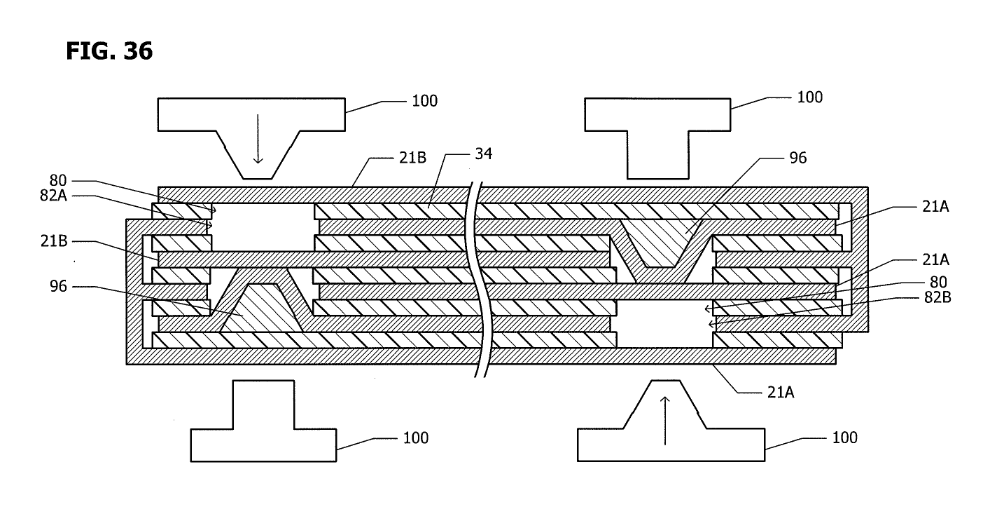

As illustrated in FIG. 36, the inner spaces of the first recess 95A and the second recess 95B are filled with thermal conducting fillers 96. For example, solder, adhesive having a high thermal conductivity or the like may be used as the thermal conducting filler 96. The outermost first thermal conducting member 21A is stacked upon the second thermal conducting member 21B with the outermost thermoelectric generating part 34 being disposed therebetween, and the outermost second thermal conducting member 21B is stacked upon the first thermal conducting member 21A with the outermost thermoelectric generating part 34 being disposed therebetween.

Portions of the outermost first thermal conducting member 21A face the middle first thermal conducting member 21A via a through holes 80 and the second through hole 82B. The facing portions are pressure bonded with each other using pressure bonding instruments 100. Similarly, portions of the outermost thermal conducting member 21B face the middle second thermal conducting member 21B via the through holes 80 and the first through hole 82A. The facing portions are pressure bonded with each other using pressure bonding instruments 100.

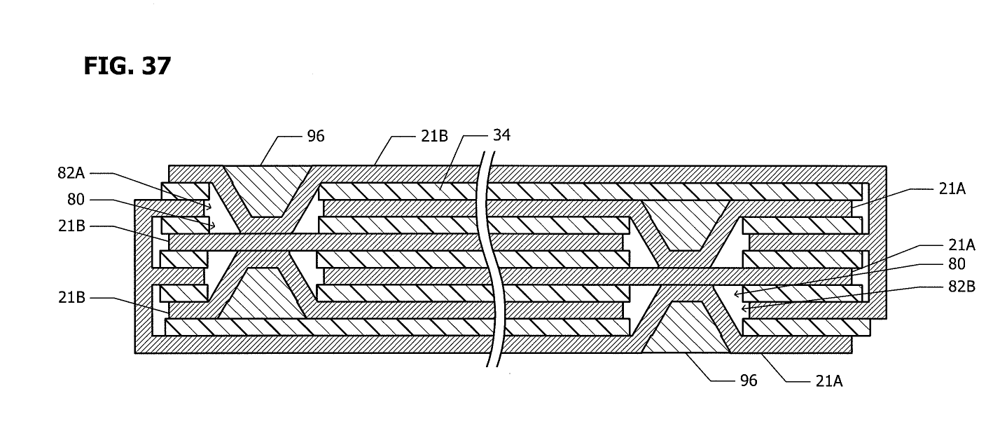

As illustrated in FIG. 37, a portion of the outermost first thermal conducting member 21A is deformed, and the deformed portion is in contact with the middle first thermal conducting member 21A via the through holes 80 and the second through hole 82B. Similarly, a portion of the outermost second thermal conducting member 21B is deformed, and the deformed portion is in contact with the middle second thermal conducting member 21B via the through holes 80 and the first through hole 82A. Recesses are formed on the outer surfaces of the outermost first and second heat conductive members 21A and 21B. The inner spaces of the recesses are filled with thermal conducting fillers 96.

The pressure bonded portion of the first thermal conducting members 21A has the same function as that of the first thermal conducting column (first thermal conducting structure) 81A of the seventeenth embodiment illustrated in FIG. 28A, and the pressure bonded portion of the second thermal conducting members 21B has the same function as that of the second thermal conducting column (second thermal conducting structure) 81B of the seventeenth embodiment illustrated in FIG. 28A. As in the case of the seventeenth embodiment, an electric generation efficiency is therefore improved. The pressure bonded portions of the thermal conducting members 21A are preferably disposed at the same position in the in-plane direction. Similarly, the pressure bonded portions of the thermal conducting members 21B are preferably disposed at the same position in the in-plane direction.

In the twentieth embodiment, since no thermal conducting column is used, the number of components is able to be reduced to realize low cost. Since the thermal conducting members are strongly bonded by pressure bonding, reliability of the thermoelectric generator is able to be improved.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A thermoelectric generator comprising:
thermoelectric generating parts having a plate-shape or film-shape and stacked in a thickness direction, each of the thermoelectric generating parts generating an electric power as a temperature difference is generated in the thickness direction;
thermal conducting members disposed between two of the thermoelectric generating parts adjacent in a stacked direction and on outer surfaces of outermost two thermoelectric generating parts;
a first thermal coupling member connected to and thermally coupled to the every other thermal conducting members disposed in the stacked direction; and
a second thermal coupling member connected to and thermally coupled to the thermal conducting members not connected to the first thermal coupling member.

2. The thermoelectric generator according to claim 1, further comprising an interlayer wiring for interconnecting two of the thermoelectric generating parts adjacent in the stacked direction.

3. The thermoelectric generator according to claim 1, wherein:
each of the thermoelectric generating parts is a partial region of a thermoelectric generating device comprising a flexible film and a thermoelectric conversion pattern formed on the flexible film and made of thermoelectric conversion material, and the thermoelectric generating parts are stacked by folding up the thermoelectric generating device.

4. The thermoelectric generator according to claim 3, wherein:
the first thermal coupling member and the thermal conducting members connected to the first thermal coupling member are formed of a first thermal conducting film disposed on one surface of the flexible film, the first thermal conducting film being configured to bend in response to folding the flexible film; and
the second thermal coupling member and the thermal conducting members connected to the second thermal coupling member are formed of a second thermal conducting film disposed on the other surface of the flexible film, the second thermal conducting film being configured to bend in response to folding the flexible film.

5. The thermoelectric generator according to claim 3, wherein:
folded portions of the thermoelectric generating device are displaced in an in-plane direction of a virtual plane perpendicular to the stacked direction.

6. The thermoelectric generator according to claim 3, wherein:
each of the thermoelectric generating parts comprises a first good thermal conductor and a second good thermal conductor, the first and second good thermal conductors being made of material having higher thermal conductivity than that of the flexible film, the first good thermal conductor being thermally coupled to the thermal conducting member connected to the first thermal coupling member, and the second good thermal conductor being thermally coupled to the thermal conducting member connected to the second thermal coupling member;
the first and second good thermal conductors are displaced from each other in an in-plane direction of a virtual plane perpendicular to the stacked direction of the thermoelectric generating parts; and
the thermoelectric conversion pattern extends from a region overlapping the first good thermal conductor to a region overlapping the second good thermal conductor.

7. The thermoelectric generator according to claim 6, wherein:
in all of the thermoelectric generating parts, the second good thermal conductor is displaced from the first good thermal conductor toward a same side in an in-plane direction of the virtual plane.

8. The thermoelectric generator according to claim 3, wherein:
a width of the folded portion of the thermoelectric generating device is narrower than a width of the thermoelectric generating part;
the first thermal coupling member is disposed along a first side wall on which the folded portions of the thermoelectric generating device appear; and
at least a portion of the first thermal coupling member is disposed within a range of a width of the thermoelectric generating part and does not disposed within a range of a width of the folded portions appearing on the first side wall.

9. The thermoelectric generator according to claim 1, wherein:
a cross sectional area of a thermal path constituted of the first thermal coupling member becomes larger toward a first side in the stacked direction, and a cross sectional area of a thermal path constituted of the second thermal coupling member becomes larger toward a second side opposite to the first side.

10. The thermoelectric generator according to claim 1, wherein:
among the thermal conducting members connected to the first thermal coupling member, the thermal conducting member disposed outermost in the stacked direction is thinnest, and the thermal conducting members becomes thicker with distance from the thermal conducting member disposed outermost; and
among the thermal conducting members connected to the second thermal coupling member, the thermal conducting member disposed outermost in the stacked direction is thinnest, and the thermal conducting members becomes thicker with distance from the thermal conducting member disposed outermost.

11. The thermoelectric generator according to claim 4, wherein:
the first thermal conducting film becomes thinner from one end in a folding direction of the flexible film to the other end, and the second thermal conducting film becomes thicker from the one end to the other end.

12. The thermoelectric generator according to claim 4, wherein:
each of the first and second thermal conducting films comprises laminated unit films,
in the first thermal conducting film, number of the unit films becomes larger from a first end to a second end in the folding direction of the flexible film, and
in the second thermal conducting film, number of the unit films becomes smaller from the first end to the second end.

13. The thermoelectric generator according to claim 1, further comprising a first thermal conducting structure configured to make thermal connection between first thermal conducting members connected to the first thermal coupling member among the thermal conducting members, the first thermal conducting structure extending through the thermoelectric generating part.

14. The thermoelectric generator according to claim 13, further comprising a second thermal conducting structure configured to make thermal connection between second thermal conducting members connected to the second thermal coupling member among the thermal conducting members, the second thermal conducting structure extending through the thermoelectric generating part.

15. The thermoelectric generator according to claim 14, wherein:
the first thermal conducting structure extends through the second thermal conducting member in a thickness direction without being in contact with the second thermal conducting member, and the second thermal conducting structure extends through the first thermal conducting member in a thickness direction without being in contact with the first thermal conducting member.

16. The thermoelectric generator according to claim 13, wherein:
the first thermal conducting structure comprises a first thermal conducting column whose both ends are fixed to surfaces facing each other of the first thermal conducting members.

17. The thermoelectric generator according to claim 13, wherein:
the first thermal conducting structure comprises jointing members respectively formed on surfaces facing each other of the first thermal conducting members, one and the other jointing members have geometrical shapes which are jointed with each other.

18. The thermoelectric generator according to claim 13, wherein:
the first thermal conducting structure comprises a thermal conducting pin extending through at least two of the first thermal conducting members and being in contact with the first thermal conducting members.

19. The thermoelectric generator according to claim 13, wherein:
the first thermal conducting structure has a structure that partial regions of the adjacent first thermal conducting members are mutually connected by pressure bonding.
